(19) United States
(12) Patent Application Publication
(10) Pub. No.: US 2020/0033522 A1
(43) Pub. Date: Jan. 30, 2020

(54) LAMINATE, DECORATIVE SHEET, AND MOLDED ARTICLE

(71) Applicant: FUJIFILM Corporation, Tokyo (JP)

(72) Inventors: Rie TAKASAGO, Kanagawa (JP); Hiroshi INADA, Kanagawa (JP); Mitsuyoshi ICHIHASHI, Kanagawa (JP)

(73) Assignee: FUJIFILM Corporation, Tokyo (JP)

(21) Appl. No.: 16/591,631

(22) Filed: Oct. 3, 2019

Related U.S. Application Data
(63) Continuation of application No. PCT/JP2018/011321, filed on Mar. 22, 2018.

(30) Foreign Application Priority Data
Apr. 6, 2017 (JP) 2017-075985

(51) Int. Cl. G02B 5/30; G02B 5/22; G02B 5/28; H05K 5/02

(52) U.S. Cl. CPC G02B 5/3016; H05K 5/0243; G02B 5/287; G02B 5/22

(57) ABSTRACT

An object of the present invention is to provide a laminate, from which a decorative sheet having metallic gloss and depth of color or the like is obtained, and a decorative sheet and a molded article which use the laminate. The object is achieved by a laminate including a colored transmission layer, a reflection layer has wavelength selectivity in reflection, and an absorption layer in this order, in which the absorption layer absorbs light transmitted through the colored transmission layer, and the reflection layer has a region reflecting the light transmitted through the colored transmission layer.

### CROSS-REFERENCE TO RELATED APPLICATIONS

This application is a Continuation of PCT International Application No. PCT/JP2018/011321 filed on Mar. 22, 2018, which claims priority under 35 U.S.C. § 119(a) to Japanese Patent Application No. 2017-075985 filed on Apr. 6, 2017. The above application is hereby expressly incorporated by reference, in its entirety, into the present application.

### BACKGROUND OF THE INVENTION

### 1. Field of the Invention

The present invention relates to a laminate, which is suitably used in a decorative sheet or the like, and a decorative sheet and a molded article which use the laminate.

### 2. Description of the Related Art

A decorative sheet with so-called metallic gloss that reflects a visible range is used, for example, in home appliances, office machines, surfaces of molded products such as automotive parts, and the like.

As such a decorative sheet, in order to make the decorative sheet have metallic gloss, a resin sheet containing metal particles is used. However, from the viewpoint of environmental load resulting from the use of heavy metals, from the viewpoint of a risk of radio interference caused in a case where the resin sheet is used in communication apparatuses such as a mobile phone, and the like, there is a demand for substitutes.

In order to meet the demand, for example, JP2007-290360A describes a resin sheet having a structure established by alternately laminating 5 or more layers formed of a resin A and 5 or more layers formed of a resin B, in which scratch processing is performed on a surface of the laminated film having at least one reflection band where a relative reflectivity becomes equal to or higher than 30% such that the thickness of an uppermost layer on the scratched side becomes larger than a maximum depth of the scratching processing.

Furthermore, JP2010-111104A describes a decorative sheet having a laminate including a resin layer having a first cholesteric regularity and a resin layer having a second cholesteric regularity, in which the resin layer having the first cholesteric regularity is a layer which transmits first circular polarization but reflects second circular polarization that is polarization different from the first circular polarization, and the resin layer having the second cholesteric regularity is disposed to reflect at least a portion of the first circular polarization transmitted through the resin layer having the first cholesteric regularity.

### SUMMARY OF THE INVENTION

In these decorative sheet, metallic gloss is realized without using a metal.

In recent years, these decorative sheets have been required to have not only metallic gloss but also depth of color, such that light and shade greatly change in a case where the decorative sheet is observed at different angles, and tint changes little even in a case where the decorative sheet is seen at different angles.

However, in the conventional decorative sheets not using metals, tint greatly changes in a case where the decorative sheets are observed at different angles, but light and shade change little in a case where the decorative sheets are observed at different angles. Therefore, in terms of depth of color, the decorative sheets are insufficient in many points and required to be further ameliorated.

An object of the present invention is to solve the problems in the conventional techniques and to provide a laminate which makes it possible to obtain a decorative sheet having metallic gloss and depth of color and a decorative sheet and a molded article which use the laminate.

In order to achieve the object, the present invention provides a laminate, a decorative sheet, and a molded article described below.
[1] A laminate comprising a colored transmission layer, a reflection layer having wavelength selectivity in reflection, and an absorption layer in this order, in which the absorption layer absorbs light transmitted through the colored transmission layer, and the reflection layer has a region reflecting the light transmitted through the colored transmission layer.
[2] The laminate described in [1], in which the reflection layer does not contain a metal.
[3] The laminate described in [1] or [2], in which the reflection layer has at least one of a cholesteric liquid crystal layer or a dielectric multilayer film.
[4] The laminate described in any one of [1] to [3], in which the absorption layer is achromatic.
[5] The laminate described in any one of [1] to [4], in which the absorption layer is black.
[6] The laminate described in any one of [1] to [5], in which a total light transmittance of the absorption layer is equal to or lower than 10%.
[7] The laminate described in any one of [1] to [6], in which the reflection layer has a transmittance equal to or lower than 70% at a central wavelength of selective reflection.
[8] The laminate described in any one of [1] to [7], in which the reflection layer has a plurality of regions, among which a central wavelength of selective reflection varies, in the same plane.
[9] The laminate described in any one of [1] to [8] having a plurality of the reflection layers.
[10] The laminate described in any one of [1] to [9], in which the reflection layer is a scattering reflection layer.
[11] The laminate described in any one of [1] to [9], in which the reflection layer is a regular reflection layer.
[12] The laminate described in any one of [1] to [11], in which the colored transmission layer has a transmittance equal to or higher than 50% at a central wavelength of selective reflection of the reflection layer.
[13] A decorative sheet having the laminate described in any one of [1] to [12].
[14] A molded article having the laminate described in any one of [1] to [12].

According to the present invention, there are provided a laminate which can realize a decorative sheet having metallic gloss and depth of color and a decorative sheet and a molded article which use the laminate and have high decorativeness.

### BRIEF DESCRIPTION OF THE DRAWINGS

FIG. 1 is a view conceptually showing an example of a decorative sheet according to an embodiment of the present invention.

FIG. 2 is a view conceptually showing another example of the decorative sheet according to the embodiment of the present invention.

FIG. 3 is a view conceptually showing a reflection layer in still another example of the decorative sheet according to the embodiment of the present invention.

FIG. 4 is a graph for illustrating the action of the decorative sheet shown in FIG. 3.

### DESCRIPTION OF THE PREFERRED EMBODIMENTS

Hereinafter, a laminate, a decorative sheet, and a molded article according to an embodiment of the present invention will be specifically described based on suitable examples illustrated in the attached drawings.

In the present specification, a range of numerical values described using “to” means a range including the numerical values listed before and after “to” as an upper limit and a lower limit.

In the present specification, “(meth)acrylate” is an expression representing either or both of acrylate and methacrylate, “(meth)acryloyl group” is an expression representing either or both of acryloyl and methacryloyl, and “(meth)acryl” is an expression representing either or both of an acryl group and a methacryl group.

In the present specification, visible light refers to light which has a wavelength visible to human eyes among electromagnetic waves and is in a range of a wavelength of 380 to 780 nm. Invisible light is light which is in a range of a wavelength shorter than 380 nm or longer than 780 nm, and infrared (infrared light) is light in a range of a wavelength longer than 780 nm and equal to or shorter than 1 mm Furthermore, among visible lights, light in a range of a wavelength of 420 to 490 nm is blue (B) light, light in a range of a wavelength of 495 to 570 nm is green (G) light, and light in a range of a wavelength of 620 to 750 nm is red (R) light, although the present invention is not limited to these.

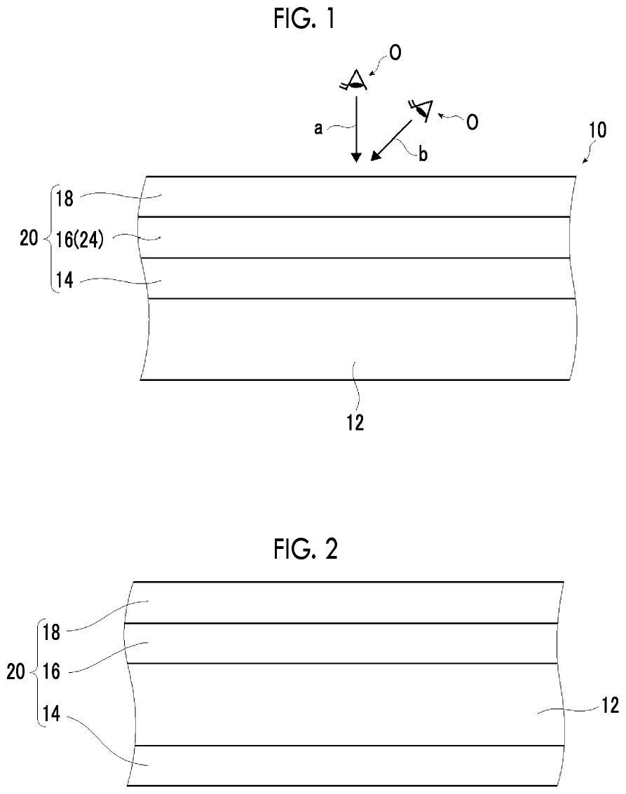

FIG. 1 conceptually shows an example of the decorative sheet according to the embodiment of the present invention using the laminate according to the embodiment of the present invention.

A decorative sheet 10 shown in FIG. 1 is constituted with a base material 12, an absorption layer 14, a reflection layer 16, and a colored transmission layer 18.

In the decorative sheet 10 illustrated in FIG. 1, the absorption layer 14, the reflection layer 16, and the colored transmission layer 18 constitute a laminate 20 according to an embodiment of the present invention. The laminate 20 according to the embodiment of the present invention is obtained by laminating the colored transmission layer 18, the reflection layer 16, and the absorption layer 14 in this order.

In the decorative sheet 10 (laminate 20), generally, the colored transmission layer 18 side is an observation side (light incident side). Accordingly, the laminate 20 according to the embodiment of the present invention is obtained by laminating the colored transmission layer 18, the reflection layer 16, and the absorption layer 14 in this order from the observation side of the decorative sheet 10.

In the laminate 20 formed of the absorption layer 14, the reflection layer 16, and the colored transmission layer 18, the absorption layer 14 is a layer absorbing the light transmitted through the colored transmission layer 18, and the reflection layer 16 is a layer reflecting (a portion of) the light transmitted through the colored transmission layer 18.

Accordingly, in a case where the colored transmission layer 18 transmits red light, the reflection layer 16 reflects the red light, and the absorption layer 14 absorbs at least the red light. In this case, the laminate 20 (decorative sheet 10) looks red.

In a case where the colored transmission layer 18 transmits green light, the reflection layer 16 reflects the green light, and the absorption layer 14 absorbs at least the green light. In this case, the laminate 20 looks green.

In a case where the colored transmission layer 18 transmits blue light, the reflection layer 16 reflects the blue light, and the absorption layer 14 absorbs at least the blue light. In this case, the laminate 20 looks blue.

### Base Material

In the decorative sheet 10, the base material 12 is a sheet-like material (a plate-like material or a film-like material), and acts as a support supporting the laminate 20 according to the embodiment of the present invention formed of the absorption layer 14, the reflection layer 16, and the colored transmission layer 18.

As the base material 12, various known resin films are suitably used.

Specifically, examples thereof include resin films formed of a cellulose resin, a polycarbonate resin, a polyester resin, a (meth)acrylic resin, a styrene resin, a polyolefin resin, a vinyl chloride resin, an amide resin, an imide resin, a sulfone resin, a polyether sulfone resin, an epoxy resin, a polystyrene resin, a polyester resin, a phenol resin, a polyether ether ketone resin, and the like. More specifically, examples thereof include resin films formed of polyethylene terephthalate (PET), triacetyl cellulose (TAC), polyethylene naphthalate (PEN), an acrylonitrile-butadiene-styrene copolymer resin (ABS resin), and the like.

As the sheet-like base material 12, it is possible to use sheet-like materials made of a metal, ceramics, paper, wood, glass, and the like.

As the sheet-like base material 12, a long sheet-like material wound in the form of a roll may be used by being wound off the roll, or a cut sheet-like base material 12 may be used.

The thickness of the sheet-like base material 12 is not particularly limited, and may be appropriately set according to the material forming the base material 12 and the like such that the base material 12 is capable of supporting the laminate 20 according to the embodiment of the present invention.

The decorative sheet and the laminate according to the embodiment of the present invention are not limited to the layer constitution illustrated in the drawing. As long as the colored transmission layer 18, the reflection layer 16, and the absorption layer 14 are laminated in this order, various layer constitutions can be used.

For example, as conceptually illustrated in FIG. 2, a constitution may be adopted in which the reflection layer 16 and the colored transmission layer 18 are laminated on one surface of the sheet-like base material 12, and the absorption layer 14 is laminated on the other surface of the base material 12.

In the present invention, the base material is not limited to the sheet-like material, and various molded products (goods) can also be used.

Specifically, examples thereof include clothing, footwear, foods, stationary, fittings, fancy goods, bedding, mats, wallpaper, toys, sporting goods, cosmetic packages (cases and containers), camera housing, interior parts of vehicles, vehicle frames, and the like formed by molding the materials listed as examples of the sheet-like material, but the present invention is not limited to these.

By using these molded products as a base material of the laminate according to the embodiment of the present invention, a molded article according to an embodiment of the present invention having the laminate according to the embodiment of the present invention is constituted.

In the decorative sheet and the molded article according to the embodiment of the present invention, for example, in a case where the base material constituted with a sheet-like material, a molded product, or the like is black and acts as the absorption layer 14 which will be described later, the base material may be used as the absorption layer 14 without providing the absorption layer 14.

In other words, in a case where the base material acts as the absorption layer 14 which will be described later, the base material may be used as the absorption layer in the laminate according to the embodiment of the present invention.

Furthermore, an alignment treatment such as rubbing may be performed on the base material 12.

### Absorption Layer

The absorption layer 14 is provided on one surface of the base material 12. Hereinafter, the base material 12 side in the decorative sheet 10 will be described as “bottom” as well, and the colored transmission layer 18 side opposite to the base material 12 side will be described as “top” as well. That is, the absorption layer 14 is provided on top of the base material 12.

As described above, the absorption layer 14 is a layer absorbing the light transmitted through the colored transmission layer 18. For example, in a case where the colored transmission layer 18 transmits red light, the absorption layer 14 may be a blue or green layer absorbing the red light.

As will be specifically described later, in a case where the laminate 20 according to the embodiment of the present invention has the absorption layer 14, the laminate 20 (the decorative sheet 10 and the molded article) has excellent metallic gloss in a case where the laminate 20 is observed. Particularly, in a case where the laminate 20 is observed from the front, excellent metallic gloss is obtained. Observing the laminate 20 from the front means that the laminate 20 is observed in a normal direction, which is in other words that the laminate 20 is observed in a direction orthogonal to the surface of the colored transmission layer 18.

As described above, the absorption layer 14 just need to be capable of absorbing the light transmitted through the colored transmission layer 18. For example, in a case where the colored transmission layer 18 transmits red light, the absorption layer 14 may be a blue or green layer absorbing the red light.

It is preferable that the absorption layer 14 absorbs all the lights which are transmitted through the colored transmission layer 18 and are not reflected from the reflection layer 16. Accordingly, it is preferable that the absorption layer 14 is capable of absorbing lights of the entire wavelength band that can be transmitted through the colored transmission layer 18.

Considering this point, the absorption layer 14 is preferably an achromatic layer having no chroma (tint), more preferably a black layer, and even more preferably a black layer capable of absorbing all the visible lights incident thereon.

It is preferable that the absorption layer 14 has low light transmitting properties. Specifically, the total light transmittance of the absorption layer 14 is preferably equal to or lower than 10%, more preferably equal to or lower than 5%, even more preferably equal to or lower than 3%, and particularly preferably equal to or lower than 1%.

In the present invention, the total light transmittance may be measured based on JIS K 7361 by using commercial measurement apparatuses such as NDH5000 and SH-7000 manufactured by NIPPON DENSHOKU INDUSTRIES Co., LTD, and the like.

The thickness of the absorption layer 14 is not particularly limited, and may be appropriately set according to the material forming the absorption layer 14 and the like such that the absorption layer 14 is capable of fully absorbing the light incident thereon, and necessary light transmitting properties (light blocking properties) are obtained.

For example, in a case where the laminate (decorative film) according to the embodiment of the present invention is used as a molding film, from the viewpoint of molding properties, the thickness of the absorption layer 14 is preferably 5 to 500 μm, and more preferably 10 to 200 μm.

The absorption layer 14 may be formed by preparing a paint containing a coloring agent (a pigment, a dye, or the like) absorbing the light of target color (wavelength band), coating the base material 12 with the paint, and drying and/or curing the paint. Alternatively, a coloring agent may be kneaded into the base material 12 such that the base material 12 acts as the absorption layer 14 as described above.

Examples of coloring agents usable in the absorption layer 14 include carbon black, a metal oxide, soot, black from plants, bond black, graphite, a nearly achromatic coloring agent obtained by mixing together several kinds of dyes and pigments, and the like.

As coating methods for coating the base material 12 with the paint, all the known methods can be used. Specifically, examples thereof include spraying (spray coating), dip coating, a printing method performed using a wire bar, an ink jet, or the like, brush coating, spin coating, and the like.

The laminate 20 may have an alignment film on a surface of the absorption layer 14 that is on the reflection layer 16 side.

As the alignment film, it is possible to use various known materials used for aligning liquid crystals and the like. Examples thereof include KURARAY POVAL PVA103, PVA203, and PVA403 (manufactured by KURARAY CO., LTD.), SUNEVER SE-130, SE-410, and SE-150 (manufactured by NISSAN CHEMICAL INDUSTRIES, LTD.), and the like.

The alignment film using these materials may be prepared through a known treatment such as rubbing, stretching, or the like.

### Reflection Layer

The reflection layer 16 is provided on top of the absorption layer 14. The reflection layer 16 reflects some of lights transmitted through the colored transmission layer 18 and has wavelength selectivity in reflection.

Accordingly, in a case where the colored transmission layer 18 transmits red light and absorbs lights of other colors, the reflection layer 16 reflects the red light and has a central wavelength of selective reflection (central wavelength of selective reflection) in a range of red (for example, 650 nm).

In a case where the colored transmission layer 18 transmits green light and absorbs lights of other colors, the reflection layer 16 reflects the green light and has a central wavelength of selective reflection in a range of green (for example, 520 nm).

In a case where the colored transmission layer 18 transmits blue light and absorbs lights of other colors, the reflection layer 16 reflects the blue light and has a central wavelength of selective reflection in a range of blue (for example, 445 nm).

In this way, in the laminate 20 according to the embodiment of the present invention, the reflection layer 16 has a region, which has a central wavelength of selective reflection positioned in a visible range, in at least a portion thereof.

The wavelength of light reflected from the reflection layer 16 is dependent on angle.

Specifically, in a case where light is incident on the reflection layer 16 from the front, the reflection layer 16 mainly reflects light having the set central wavelength of selective reflection. In contrast, in a case where light is obliquely incident on the reflection layer 16, the selective reflection wavelength (the central wavelength of selective reflection) moves (shifts) to a short wavelength side. That is, according to the angle of light incident on the reflection layer 16, the color of light to be reflected shifts to a short wavelength side.

In a case where the laminate 20 has the reflection layer 16, even though the reflection layer 16 does not contain a metal, a laminate 20 having metallic gloss can be obtained.

Examples of the reflection layer 16 include a layer obtained by fixing a cholesteric liquid crystalline phase and a dielectric multilayer film.

### Layer Obtained by Fixing Cholesteric Liquid Crystalline Phase

In the laminate 20 according to the embodiment of the present invention, as the reflection layer 16, a layer obtained by fixing a cholesteric liquid crystalline phase is preferably used. Hereinafter, “layer obtained by fixing a cholesteric liquid crystalline phase” will be described as “cholesteric liquid crystal layer” as well.

The reflection layer 16 formed of the cholesteric liquid crystal layer may be constituted with a single layer or a plurality of layers.

As the cholesteric liquid crystal layer, as long as the alignment of a liquid crystal compound having turned into a cholesteric liquid crystalline phase is retained on the layer, known layers can be used without particular limitation.

Examples of the cholesteric liquid crystal layer include a layer obtained by aligning a polymerizable liquid crystal compound, which will be described later, in a cholesteric liquid crystalline phase and then polymerizing the compound by the irradiation of light (for example, ultraviolet rays and the like) or heating.

As long as the optical characteristics of the cholesteric liquid crystalline phase are retained in the cholesteric liquid crystal layer, the liquid crystal compound in the layer may not exhibit liquid crystallinity all the time. For example, the polymerizable liquid crystal compound may lose liquid crystallinity by becoming a high-molecular-weight compound through a curing reaction.

The cholesteric liquid crystal layer selectively reflects circular polarization according to the helical structure of the cholesteric liquid crystal. A central wavelength λ (central wavelength of selective reflection) of the selective reflection of circular polarization is dependent on a pitch P (=pitch of helix) of the helical structure in the cholesteric liquid crystalline phase, and has a relationship of λ=n×P with an average refractive index n of the cholesteric liquid crystal layer. Therefore, by controlling the pitch of the helical structure, the wavelength at which circular polarization is selectively reflected can be adjusted.

The pitch of the cholesteric liquid crystalline phase is dependent, for example, on the type and/or content of a chiral agent in a polymerizable liquid crystal composition which will be described later. Therefore, by adjusting the type and/or content of the chiral agent, a desired pitch can be obtained.

In a case where the laminate 20 has two reflection layers 16 formed of the cholesteric liquid crystal layer, the selective reflection wavelengths of the cholesteric liquid crystal layers may be the same as or different from each other.

The sense of circular polarization selectively reflected from the cholesteric liquid crystal layer is the same as the sense of the helix. That is, the cholesteric liquid crystal layer with a right-handed helix selectively reflects right circular polarization, and the cholesteric liquid crystal layer with a left-handed helix selectively reflects left circular polarization.

In a case where the laminate 20 has two reflection layers 16 formed of cholesteric liquid crystal layers, the senses of the cholesteric liquid crystal layers may be the same as or different from each other.

For measuring the sense and pitch of the helix, it is possible to use the methods described in “Introduction to Experiment of Liquid Crystal Chemistry” edited by The Japanese Liquid Crystal Society, Sigma Publication Ltd, 2007, p. 46 and “Handbook of Liquid Crystal”, Editorial Committee of Handbook of Liquid Crystal, MARUZEN Co., Ltd. p. 196.

A half-width Δλ (nm) of a selective reflection band (reflection layer 16) of circular polarization reflected from the cholesteric liquid crystal layer is dependent on a birefringence Δn of a liquid crystal compound and the pitch P described above, and has a relationship of Δλ=Δn×P. Therefore, by adjusting Δn, the width of the selective reflection band can be controlled. Δn can be controlled by the type of the polymerizable liquid crystal compound, which will be described later, and/or the temperature at the time of fixing the alignment, and the like.

The central wavelength and the half-width of the selective reflection of the cholesteric liquid crystal layer can be determined by the following method.

In a case where a transmission spectrum of the cholesteric liquid crystal layer is measured using a spectrophotometer UV3150 (manufactured by Shimadzu Corporation), transmittance falling peaks are found in a selective reflection region. Provided that the value of a wavelength of a short wavelength side is λ1 (nm) and the value of a wavelength of a long wavelength side is λ2 (nm) between two wavelengths at which the transmittance becomes equal to a height which is ½ of the height of the maximum peak, the central wavelength of selective reflection and the half-width of the selective reflection can be represented by the following formulae.

Central wavelength=(λ1+λ2)/2

Half-width=(λ2−λ1)

Generally, in a case where one kind of material is used, the half-width of a selective reflection band is about 50 to 150 nm. In order to widen the selective reflection band, two or more kinds of cholesteric liquid crystal layers, among which the pitch P and the central wavelength of reflected light varies, may be laminated. Furthermore, by slightly changing the pitch P in a film thickness direction in one cholesteric liquid crystal layer, a control wavelength band can be widened.

The cholesteric liquid crystal layer can be prepared using a liquid crystal composition containing a liquid crystal compound. Particularly, in view of more conveniently obtaining the cholesteric liquid crystal layer, it is preferable that the cholesteric liquid crystal layer is prepared using a polymerizable liquid crystal composition containing a liquid crystal compound (a polymerizable liquid crystal compound) containing a polymerizable group.

### Polymerizable Liquid Crystal Composition

As the polymerizable liquid crystal composition, as long as the composition contains a polymerizable liquid crystal compound, known polymerizable liquid crystal compositions can be used without particular limitation.

The polymerizable liquid crystal composition may contain, as components other than the polymerizable liquid crystal compound, for example, a solvent, a chiral agent, a polymerization initiator, an alignment control agent, a surfactant, and the like. Hereinafter, the components contained in the polymerizable liquid crystal composition will be described.

### Polymerizable Liquid Crystal Compound

As the polymerizable liquid crystal compound, as long as the compound is a liquid crystal compound containing a polymerizable group, known polymerizable liquid crystal compounds can be used without particular limitation.

The content of the polymerizable liquid crystal compound in the polymerizable liquid crystal composition is not particularly limited, but is preferably 70% to 95% by mass in general with respect to the total solid content in the polymerizable liquid crystal composition.

One kind of polymerizable liquid crystal compound may be used singly, or two or more kinds of polymerizable liquid crystal compounds may be used in combination. In a case where two or more kinds of polymerizable liquid crystal compounds are used in combination, the total content thereof is preferably within the above range.

As the polymerizable group contained in the polymerizable liquid crystal compound, known polymerizable groups can be used without particular limitation.

As the known polymerizable groups, for example, the polymerizable groups described in paragraphs “0161” to “0171” in JP2002-129162A can be used. What are described in the paragraphs are incorporated into the present specification. As the polymerizable group, an ethylenically unsaturated double bond group is preferable, and at least one kind of polymerizable group selected from the group consisting of an acryloyl group and a methacryloyl group is more preferable.

Examples of the polymerizable liquid crystal compound include a compound represented by General Formula (1) or General Formula (3) shown below.

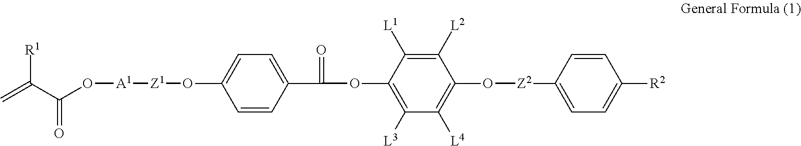

In General Formula (1), A¹ represents a methylene group having 2 to 18 carbon atoms, one CH₂ group or two or more CH₂ groups not being adjacent to each other in the methylene group may be substituted with —O—; Z¹ represents —CO—, —O—CO—, or a single bond; Z² represents —CO—or CO—CH═CH—; R¹ represents a hydrogen atom or a methyl group; R² represents a hydrogen atom, a halogen atom, a linear alkyl group having 1 to 4 carbon atoms, a methoxy group, an ethoxy group, an aromatic ring group which may have a substituent, a cyclohexyl group, a vinyl group, a formyl group, a nitro group, a cyano group, an acetyl group, an acetoxy group, a N-acetylamide group, an acryloylamino group, a N,N-dimethylamino group, a maleimide group, a methacryloylamino group, an aryloxy group, an acryloxycarbamoyloxy group, a N-alkyloxycarbamoyl group with an alkyl group having 1 to 4 carbon atoms, a N-(2-methacryloyloxyethyl)carbamoyloxy group, a N-(2-acryloyloxyethyl)carbamoyl group, or a structure represented by Formula (1-2); L¹, L², L³, and L⁴ each independently represent an alkyl group having 1 to 4 carbon atoms, an alkoxy group having 1 to 4 carbon atoms, an alkoxycarbonyl group having 2 to 5 carbon atoms, an acyl group having 2 to 4 carbon atoms, a halogen atom, or a hydrogen atom, and at least one of L¹, L², L³, or L⁴ represents a group other than a hydrogen atom.

—Z⁵-T-Sp-P Formula (1-2)

In Formula (1-2), P represents an acryl group, a methacryl group, or a hydrogen atom; Z⁵ represents a single bond, —COO—, —CONR¹— (R¹ represents a hydrogen atom or a methyl group), or —COS—; T represents a 1,4-phenylene group; Sp represents a divalent aliphatic group having 1 to 12 carbon atoms that may have a substituent, and one CH2 group or two or more CH₂ groups not being adjacent to each other in the aliphatic group may be substituted —O—, —S—, —OCO—, —COO—, or OCOO—.

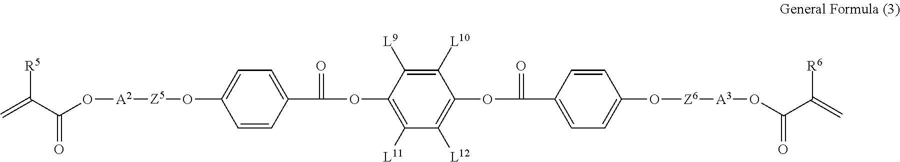

In General Formula (3), A² and A³ each independently represent a methylene group having 2 to 18 carbon atoms, one CH₂ group or two or more CH₂ groups not being adjacent to each other in the methylene group may be substituted —O—; Z⁵ represents —CO—, —OCO—, or a single bond; Z⁶ represents —CO—, —COO—, or a single bond; R⁵ and R⁶ each independently represent a hydrogen atom or a methyl group; L⁹, L¹⁰, L¹¹, and L¹² each independently represent an alkyl group having 1 to 4 carbon atoms, an alkoxy group having 1 to 4 carbon atoms, an alkoxycarbonyl group having 2 to 5 carbon atoms, an acyl group having 2 to 4 carbon atoms, a halogen atom, or a hydrogen atom; and at least one of L⁹, L¹⁰, L¹¹, or L¹² represents a group other than a hydrogen atom.

As the polymerizable liquid crystal compound, in addition to the above compounds, the liquid crystal compounds described in paragraphs “0015” to “0036” in JP2014-198814A can be used. What are described in the paragraphs are incorporated into the present specification.

In view of further improving the curing properties of the polymerizable liquid crystal composition, particularly, in view of curing the polymerizable liquid crystal composition in a shorter time and in view of inhibiting the crystallization of the polymerizable liquid crystal compound, it is preferable that the polymerizable liquid crystal composition contains, as the polymerizable liquid crystal compound described above, a liquid crystal compound 1 containing one or more polymerizable groups, each of which is at least one kind of polymerizable group selected from the group consisting of an acryloyl group and a methacryloyl group, in one molecule and a liquid crystal compound 2 containing two or more polymerizable groups described above in one molecule.

Particularly, in view of curing the obtained cholesteric liquid crystal layer in a shorter time and obtaining further improved durability and hardness, it is preferable that the liquid crystal compound 1 contains two or more polymerizable groups, each of which is at least one kind of polymerizable group selected from the group consisting of an acryloyl group and a methacryloyl group, in one molecule.

In the present specification, the liquid crystal compound 1 and the liquid crystal compound 2 are compounds different from each other.

In a case where the polymerizable liquid crystal composition contains polymerizable liquid crystal compounds different from each other (the liquid crystal compound 1 and the liquid crystal compound 2), the polymerizable liquid crystal compounds in the polymerizable liquid crystal composition are hardly crystallized. The polymerizable liquid crystal composition has further improved temporal stability. Furthermore, a layer of the polymerizable liquid crystal composition formed using the polymerizable liquid crystal composition maintains further improved temporal stability while being irradiated with ultraviolet rays after being formed (for example, after being formed by spraying), and the surface condition of the obtained cholesteric liquid crystal layer is further improved.

The content of the liquid crystal compound 1 in the polymerizable liquid crystal composition is not particularly limited, but is preferably 5% to 90% by mass in general with respect to the total solid content in the polymerizable liquid crystal composition.

The content of the liquid crystal compound 2 in the polymerizable liquid crystal composition is not particularly limited, but is preferably 5% to 90% by mass in general with respect to the total solid content in the polymerizable liquid crystal composition.

### Solvent

It is preferable that the polymerizable liquid crystal composition contains a solvent.

As the solvent, known solvents can be used without particular limitation as long as the solvents are capable of dissolving or dispersing the components of the polymerizable liquid crystal composition. Examples of the solvent include water and/or an organic solvent. It is preferable that the polymerizable liquid crystal composition contains an organic solvent.

The content of the solvent in the polymerizable liquid crystal composition is not particularly limited. The solid contents in the polymerizable liquid crystal composition are preferably adjusted to be 1% to 50% by mass, and more preferably adjusted to be 1% to 20% by mass. Particularly, in a case where the cholesteric liquid crystal layer is formed by spraying the polymerizable liquid crystal composition to a member, the solid contents of the polymerizable liquid crystal composition is even more preferably adjusted to be 1% to 10% by mass.

One kind of solvent may be used singly, or two or more kinds of solvents may be used in combination. In a case where two or more kinds of solvents are used in combination, the total content thereof is preferably within the above range.

Examples of the organic solvent include butyl ether, dimethoxyethane, diethoxyethane, propylene oxide, 1,4-dioxane, 1,3-dioxolane, 1,3,5-trioxane, tetrahydrofuran, anisole, phenetole, dimethyl carbonate, methyl ethyl carbonate, diethyl carbonate, acetone, methyl ethyl ketone (MEK), diethyl ketone, dipropyl ketone, diisobutyl ketone, cyclopentanone, cyclohexanone, methyl cyclohexanone, ethyl formate, propyl formate, pentyl formate, methyl acetate, ethyl acetate, propyl acetate, methyl propionate, ethyl propionate, γ-butyrolactone, methyl 2-methoxyacetate, methyl 2-ethoxyacetate, ethyl 2-ethoxyacetate, ethyl 2-ethoxypropionate, 2-methoxyethanol, 2-propoxyethanol, 2-butoxyethanol, 1,2-diacetoxyacetone, acetyl acetone, diacetone alcohol, methyl acetoacetate, ethyl acetoacetate, methyl alcohol, ethyl alcohol, isopropyl alcohol, n-butyl alcohol, cyclohexyl alcohol, isobutyl acetate, methyl isobutyl ketone (MIBK), 2-octanone, 2-pentanone, 2-hexanone, ethylene glycol ethyl ether, ethylene glycol isopropyl ether, ethylene glycol butyl ether, propylene glycol methyl ether, ethyl carbitol, butyl carbitol, hexane, heptane, octane, cyclohexane, methyl cyclohexane, ethyl cyclohexane, benzene, toluene, xylene, and the like.

The boiling point of the solvent is not particularly limited. In a case where the cholesteric liquid crystal layer is formed by spraying the polymerizable liquid crystal composition to a member, in view of making it possible to obtain a smoother cholesteric liquid crystal layer and secure sufficient working hours, the boiling point of the solvent is preferably 35° C. to 180° C., and more preferably 55° C. to 150° C.

In a case where two or more kinds of solvents are used in combination, the boiling point means the boiling point of a mixture obtained by mixing together the solvents used in combination. Furthermore, the boiling point means a boiling point at 1 atm.

The solubility parameter of the solvent is not particularly limited. In view of making it easier to dissolve the polymerizable liquid crystal compound and obtain a smoother cholesteric liquid crystal layer, the solubility parameter of the solvent is preferably 7.5 to 12, and more preferably 8 to 9. The unit of the solubility parameter is (cal/cm³)^{1/2}.

### Preferred Aspect of Polymerizable Liquid Crystal Composition

In a case where the polymerizable liquid crystal composition contains the liquid crystal compound 1 containing one or more polymerizable groups, each of which is at least one kind of polymerizable group selected from the group consisting of an acryloyl group and a methacryloyl group, in one molecule, and the liquid crystal compound 2 containing two or more polymerizable groups in one molecule, and the solvent has a solubility parameter of 8 to 9 and a boiling point of 55° C. to 150° C., it is possible to obtain a cholesteric liquid crystal layer with fewer defects than in a case where the polymerizable liquid crystal composition is used as a spray ink. The spray ink means a composition used by being sprayed to a member so as to form a cholesteric liquid crystal layer on top of the member.

### Chiral Agent (Optically Active Compound)

The polymerizable liquid crystal composition may contain a chiral agent. The chiral agent induces a helical structure of a cholesteric liquid crystalline phase such that a cholesteric liquid crystalline phase is easily obtained. As the chiral agent, known chiral agents can be used without particular limitation.

The content of the chiral agent in the polymerizable liquid crystal composition is not particularly limited, but is preferably 1% to 15% by mass in general with respect to the total mass of the polymerizable liquid crystal compound.

One kind of chiral agent may be used singly, or two or more kinds of chiral agents may be used in combination. In a case where two or more kinds of chiral agents are used in combination, the total content thereof is preferably within the above range.

As known chiral agents, for example, it is possible to use the compounds described in Handbook of Liquid Crystal Device, Chapter 3, 4-3, Chiral agents for Twisted Nematic (TN) and Super-twisted nematic display (STN), p. 199, edited by the 142^{nd} committee of Japan Society for The Promotion of Science, 1989, isosorbide, isomannide derivatives, and the like.

Generally, the chiral agent contains asymmetric carbon atoms. However, an axially asymmetric compound or a planarly asymmetric compound not containing asymmetric carbon atoms can also be used as the chiral agent. Examples of the axially asymmetric compound and the planarly asymmetric compound include binaphthyl, helicene, paracyclophane, derivatives of these, and the like.

The chiral agent may have a polymerizable group. In a case where the chiral agent has a polymerizable group, by a polymerization reaction between the polymerizable chiral agent and the polymerizable liquid crystal compound, it is possible to form a polymer having a repeating unit derived from the polymerizable liquid crystal compound and a repeating unit derived from the chiral agent. In this aspect, the polymerizable group contained in the polymerizable chiral agent is preferably the same type of polymerizable group as the polymerizable group contained in the polymerizable liquid crystal compound. Accordingly, the polymerizable group of the chiral agent is more preferably an ethylenically unsaturated group, an epoxy group, or an aziridinyl group, and more preferably an ethylenically unsaturated group. Furthermore, the chiral agent may be a liquid crystal compound.

It is preferable that the chiral agent has a photoisomerizing group because then a pattern of an intended reflection wavelength corresponding to an emission wavelength can be formed by irradiating the polymerizable liquid crystal composition with actinic rays or the like through a photomask after coating and alignment. As the photoisomerizing group, an isomerizing site of a compound exhibiting photochromic properties, an azo group, an azoxy group, and a cinnamoyl group are preferable. Specifically, it is possible to use compounds described in JP2002-080478A, JP2002-080851A, JP2002-179668A, JP2002-179669A, JP2002-179670A, JP2002-179681A, JP2002-179682A, JP2002-338575A, JP2002-338668A, JP2003-313189A, JP2003-313292A, and the like. Furthermore, examples of commercial chiral agents include PALIOCOLOR LC-756 (manufactured by BASF SE) and the like.

### Polymerization Initiator

It is preferable that the polymerizable liquid crystal composition contains a polymerization initiator.

The content of the polymerization initiator in the polymerizable liquid crystal composition is not particularly limited. However, in view of imparting sufficient curing properties, the content of the polymerization initiator with respect to the total solid content in the polymerizable liquid crystal composition is preferably 0.5% to 10% by mass, and more preferably 1% to 5% by mass.

One kind of polymerization initiator may be used singly, or two or more kinds of polymerization initiators may be used in combination. In a case where two or more kinds of polymerization initiators are used in combination, the total content thereof is preferably within the above range.

The polymerization initiator can be appropriately selected from known polymerization initiators without particular limitation. For example, a polymerization initiator having photosensitivity (so-called photopolymerization initiator) is preferable. In addition to the photopolymerization initiator, a thermal polymerization initiator can also be used, and the photopolymerization initiator and the thermal polymerization initiator can be used in combination as well.

As the photopolymerization initiator, known photopolymerization initiators can be used without particular limitation as long as the photopolymerization initiator is capable of initiating the polymerization of a polymerizable compound.

As the photopolymerization initiator, for example, a compound exhibiting photosensitivity in a range of ultraviolet rays to visible light is preferable. Furthermore, the photopolymerization initiator may be an activator which generates active radicals by interacting in a certain way with a photoexcited sensitizer or an initiator which initiates cationic polymerization according to the type of the polymerizable compound.

Examples of the photopolymerization initiator include acetophenones, benzophenones, Michler's benzoyl benzoates, α-amyloxime esters, phosphine oxides, ketals, anthraquinones, thioxanthones, propiophenones, an azo compound, peroxides, 2,3-dialkyl dione compounds, disulfide compounds, fluoroamine compounds, benzyls, benzoins, aromatic diazoniums, an aromatic sulfonium salt, an aromatic iodonium salt, a metallocene compound, a benzoin sulfonic acid ester, lophine dimers, onium salts, borate salts, active esters, active halogens, an inorganic complex, coumarins, acyl phosphine oxides, and the like.

Specific examples, preferred aspects, commercial products, and the like of the photopolymerization initiator are described in paragraphs “0133” to “0151” in JP2009-098658A. What are described in the paragraphs are incorporated into the present specification. Examples of commercial products of the photopolymerization initiator include IRGACURE 819 (bis(2,4,6-trimethybenzoyl)-phenyl phosphine oxide, manufactured by BASF SE) and the like.

### Sensitizer

It is preferable that the polymerizable liquid crystal composition contains a sensitizer. As the sensitizer, known sensitizers can be used without particular limitation.

The content of the sensitizer in the polymerizable liquid crystal composition is not particularly limited, but is preferably 0.1% to 20% by mass in general with respect to 100 parts by mass of the polymerization initiator.

One kind of sensitizer may be used singly, or two or more kinds of sensitizers may be used in combination. In a case where two or more kinds of sensitizers are used in combination, the total content thereof is preferably within the above range.

Examples of the sensitizer include n-butyl amine, triethyl amine, tri-n-butyl phosphine, and thioxanthone. Examples of commercial sensitizers include a “KAYACURE” (trade name) series manufactured by Nippon Kayaku Co., Ltd., and the like.

### Alignment Control Agent

The polymerizable liquid crystal composition may contain an alignment control agent. As the alignment control agent, known alignment control agents can be used without particular limitation.

The content of the alignment control agent in the polymerizable liquid crystal composition is not particularly limited, but is preferably 0.05% to 10% by mass in general with respect to the total solid content in the polymerizable liquid crystal composition. One kind of alignment control agent may be used singly, or two or more kinds of alignment control agents may be used in combination. In a case where two or more kinds of alignment control agents are used in combination, the total content thereof is preferably within the above range.

As the alignment control agent, for example, a low-molecular-weight alignment control agent or a high-molecular-weight alignment control agent can be used. For the low-molecular-weight alignment control agent, for example, the description in paragraphs “0009” to “0083” in JP2002-020363A, paragraphs “0111” to “0120” in JP2006-106662A, and paragraphs “0021” to “0029” in JP2012-211306A can be referred to. What are described in the paragraphs are incorporated into the present specification. For the high-molecular-weight alignment control agent, for example, the description in paragraphs “0021” to “0057” in JP2004-198511A and paragraphs “0121” to “0167” in JP2006-106662A can be referred to. What are described in the paragraphs are incorporated into the present specification.

In a case where the alignment control agent is used, for example, it is easier for the liquid crystal compound to be in a homogeneous alignment state in which the compound is aligned in parallel with the surface of the layer.

### Surfactant

It is preferable that the polymerizable liquid crystal composition contains a surfactant. As the surfactant, known surfactants can be used without particular limitation.

The content of the surfactant in the polymerizable liquid crystal composition is not particularly limited, but is preferably 0.05% to 10% by mass in general with respect to the total solid content in the polymerizable liquid crystal composition. Particularly, in a case where the cholesteric liquid crystal layer is formed by spraying the polymerizable liquid crystal composition to a member, the content of the surfactant is more preferably 2% to 10% by mass. In a case where the content of the surfactant contained in the polymerizable liquid crystal composition is 2% to 10% by mass, the surface condition of the cholesteric liquid crystal layer formed by spraying the polymerizable liquid crystal composition is further improved. In the present specification, the surface condition means the uniformity within a surface (a state where cissing of the polymerizable liquid crystal composition does not occur and color unevenness does not occur within a surface).

One kind of surfactant may be used singly, or two or more kinds of surfactants may be used in combination. In a case where two or more kinds of surfactants are used in combination, the total content thereof is preferably within the above range.

Examples of the surfactant include a silicone-based surfactant and a fluorine-based surfactant. Between these, a fluorine-based surfactant is preferable.

Specific examples of the surfactant include the compounds described in paragraphs “0082” to “0090” in JP2014-119605A, the compounds described in paragraphs “0031” to “0034” in JP2012-203237A, the compound described in paragraphs “0092” and “0093” in JP2005-099248A, the compounds described in paragraphs “0076” to “0078” and paragraphs “0082” to “0085” in JP2002-129162A, the compounds described in paragraphs “0018” to “0043” in JP2007-272185A, and the like.

As the method for forming a reflection layer by using the polymerizable liquid crystal composition, known methods can be used without particular limitation.

For example, the reflection layer may be formed by preparing the polymerizable liquid crystal composition, coating the absorption layer 14 or the base material 12 (see FIG. 2) with the polymerizable liquid crystal composition by known methods such as spraying exemplified above regarding the coating of the base material 12 with a paint, drying the composition if necessary, then aligning the polymerizable liquid crystal compound in a cholesteric liquid crystalline phase, and then performing light irradiation or heating.

### Dielectric Multilayer Film

As the reflection layer 16, a dielectric multilayer film can also be suitably used.

As the dielectric multilayer film, it is possible to use various known multilayer films, which are formed by laminating a plurality of layers such as resin layers having different birefringences, according to the intended central wavelength of selective reflection of the reflection layer 16.

Furthermore, as the dielectric multilayer film, it is possible to use commercial products such as a PICASUS series manufactured by TORAY INDUSTRIES, INC., an AMAZING FILM series manufactured by NICHIEI KAKOH CO., LTD., “MAGICAL FILM” marketed from HOLOGRAM SUPPLY, and DICHROIC FILTERS (manufactured by KenkoTokina Corporation and the like).

The laminate according to the embodiment of the present invention may have a reflection layer constituted with a plurality of layers including the cholesteric liquid crystal layer and the dielectric multilayer film.

The light transmittance of the reflection layer 16 is not particularly limited. The transmittance of the reflection layer 16 at a central wavelength of selective reflection is preferably equal to or lower than 70%, more preferably equal to or lower than 60%, even more preferably equal to or lower than 55%, and particularly preferably equal to or lower than 50%.

It is considered that the reflection layer 16 may reflect all the lights except for the light transmitted through the reflection layer 16. Accordingly, by making the reflection layer 16 have a transmittance equal to or higher than 70% at the central wavelength of selective reflection, in a case where the laminate 20 is observed, excellent metallic gloss with intended tint can be obtained.

The transmittance at the central wavelength of selective reflection may be measured using commercial measurement apparatuses such as a spectrophotometer UV3150 (manufactured by Shimadzu Corporation).

The reflection layer 16 may be a scattering reflection layer or a regular reflection layer.

Provided that the reflection layer 16 is a regular reflection layer, light and shade greatly change in a case where the observation direction is changed as will be described later. Provided that the reflection layer 16 is a scattering reflection layer, light and shade change little even in a case where the observation direction is changed will be described later.

As described above, the regular reflection layer 16 can be obtained by forming an alignment film on top of the absorption layer 14 and forming the reflection layer 16 on top of the alignment film. Alternatively, a surface on which the reflection layer 16 will be formed may be treated by means of rubbing or the like such that the surface on which the reflection layer 16 will be formed acts as an alignment film.

In contrast, the scattering reflection layer 16 can be obtained by forming the reflection layer 16 without providing an alignment film so as to obtain the reflection layer 16 having lots of alignment defects. Furthermore, the scattering reflection layer 16 can be obtained by forming a resin layer without anisotropy on top of the absorption layer 14 and forming the reflection layer 16 on top of the resin layer.

In the laminate 20 according to the embodiment of the present invention, if necessary, various layers expressing optical actions may be provided in combination with the reflection layer 16.

For example, the reflection layer 16 and a phase difference layer such as a λ/2 plate may be provided in combination. This constitution will be specifically described later.

### Colored Transmission Layer 18

In the laminate 20, the colored transmission layer 18 is provided on top of the reflection layer 16.

The colored transmission layer 18 is a layer which transmits light of predetermined color (wavelength band) and absorbs lights of other colors.

As described above, in the laminate according to the embodiment of the present invention, the reflection layer 16 reflects the light transmitted through the colored transmission layer 18, and the absorption layer 14 absorbs the light transmitted through the colored transmission layer 18. Accordingly, in a case where the colored transmission layer 18 transmits red light, the reflection layer 16 reflects the red light, and the absorption layer 14 absorbs the red light. More specifically, the reflection layer 16 has a central wavelength of selective reflection in a band of red light.

The total light transmittance of the colored transmission layer 18 is preferably equal to or higher than 50%, more preferably equal to or higher than 55%, and even more preferably equal to or higher than 60%.

Furthermore, the transmittance of the colored transmission layer 18 at the central wavelength of selective reflection of the reflection layer 16 is preferably equal to or higher than 50%, more preferably equal to or higher than 60%, and even more preferably equal to or higher than 70%.

It is preferable that the colored transmission layer 18 has a total light transmittance equal to or higher than 50% and/or a transmittance equal to or higher than 50% at the central wavelength of selective reflection of the reflection layer 16, because then the depth of color of the laminate 20 becomes suitable, and excellent metallic gloss is obtained. The depth of color will be specifically described later.

As the colored transmission layer 18, it is possible to use various known so-called color filters such as a layer formed of a coloring agent and a binder and a commercial clear paint that transmit light in a specific wavelength band, particularly, light in a specific wavelength band of visible light and absorb light of other wavelengths.

The colored transmission layer 18 may be formed, for example, by preparing a paint containing a coloring agent and a binder, coating the reflection layer 16 with the prepared paint by known methods such as spraying exemplified above regarding the coating of the base material 12 with a paint, and then drying and/or curing the paint.

Furthermore, as the colored transmission layer 18, commercial color filters such as colored cellophane, a clear cutting sheet, and a colored vinyl chloride sheet may be used.

### Action of Laminate

Hereinafter, the action of the laminate 20 will be described so as to more specifically explain the laminate, the decorative sheet, and the molded article according to the embodiment of the present invention.

For example, the laminate 20 looks red; the colored transmission layer 18 transmits red light and absorbs lights of other colors; the reflection layer 16 is formed of the aforementioned cholesteric liquid crystal layer having a central wavelength of selective reflection in a range of red light (for example, 650 nm) and reflects red right circular polarization; and the absorption layer 14 is black and absorbs all the visible lights including the light transmitted through the colored transmission layer 18.

As described above, in the laminate 20, the colored transmission layer 18 side is an observation side. That is, the colored transmission layer 18 side is a light incident side.

First, as shown in FIG. 1 by an arrow a in a case where an observer O observes the laminate 20 (decorative sheet 10) from the front, that is, in a case where lights are incident on the laminate 20 from the front, the visible lights incident on the laminate 20 are incident on the colored transmission layer 18 first. Among the visible lights incident on the colored transmission layer 18, only red lights are transmitted through the colored transmission layer 18, and other components are absorbed into the colored transmission layer 18.

The lights transmitted through the colored transmission layer 18 are then incident on the reflection layer 16. Among the lights incident on the reflection layer 16, only right circular polarization of red light is reflected from the reflection layer 16, and other lights are transmitted through the reflection layer 16.

The lights transmitted through the reflection layer 16 are then incident on the absorption layer 14. As described above, the absorption layer 14 is black. Accordingly, all the visible lights incident on the absorption layer 14 are absorbed into the absorption layer 14 and are never reflected.

In contrast, the lights reflected from the reflection layer 16 are incident on the colored transmission layer 18 again. The reflection layer 16 reflects red light, and the colored transmission layer 18 transmits red light. Therefore, red light is observed by the observer. Consequently, what the observer O observes is only the red light reflected from only the reflection layer 16 (cholesteric liquid crystal layer). Accordingly, a red laminate 20 (decorative sheet 10) having metallic gloss is observed by the observer O.

In contrast, as shown in FIG. 1 by an arrow b, in a case where the observer O obliquely observes the laminate 20 or in a case where the observer O bends the decorative sheet 10 and observes the decorative sheet 10 without changing the observation direction, the laminate 20 looks different from the laminate 20 observed from the front.

That is, in a case where the observer O observes the laminate 20 in a direction forming an angle with a normal line of the surface (a line orthogonal to the surface) of the colored transmission layer 18, the laminate 20 looks different from the laminate 20 observed from the normal direction (front).

In a case where the observer O obliquely observes the laminate 20, that is, in a case where light is obliquely incident on the laminate, similarly to the above, among visible lights, only the components of red light are transmitted through the colored transmission layer 18, and other components are absorbed into the colored transmission layer 18.

The lights transmitted through the colored transmission layer 18 are incident on the reflection layer 16 similarly to the above. Among the lights incident on the reflection layer 16, similarly to the above, only right circular polarization in a predetermined wavelength band is reflected, and other lights are transmitted through the reflection layer 16, and all the visible lights are absorbed into the absorption layer 14.

The reflection wavelength (central wavelength of selective reflection) of the reflection layer 16 (cholesteric liquid crystal layer) is dependent on an angle. In a case where light is obliquely incident on the reflection layer 16, the wavelength of light to be reflected moves (shifts) to a short wavelength side.

In the example illustrated in the drawing, the reflection layer 16 is set such that the reflection layer 16 reflects right circular polarization of red light in a state where lights are incident thereon from the front. Therefore, in a case where lights are obliquely incident on the reflection layer 16, light having a wavelength close to that of green light having a short wavelength is reflected from the reflection layer 16.

As described above, the colored transmission layer 18 transmits only red light. Accordingly, the lights incident on the reflection layer 16 contain an extremely small amount of green light components. That is, in a case where lights are obliquely incident on the reflection layer 16, the amount of light components reflected from the reflection layer 16 is greatly reduced. Furthermore, in a case where lights are obliquely incident on the cholesteric liquid crystal layer, a reflection efficiency thereof is reduced.

Consequently, in a case where the laminate 20 is obliquely observed, brightness of the laminate 20 the observer O observes is greatly reduced.

Meanwhile, the laminate 20 has the colored transmission layer 18, which transmits only red light and absorbs other visible lights, as an uppermost layer on the observation side.

Accordingly, only red light is reflected from the laminate 20 and observed by the observer O. That is, even though the observer O observes the laminate 20 in any direction, the laminate 20 looks red, and the tint changes little.

In other words, in a case where the laminate 20 according to the embodiment of the present invention is observed at different angles, light and shade greatly change (light and shade are greatly dependent on a viewing angle). Furthermore, even though the laminate 20 according to the embodiment of the present invention is observed at different angles, the tint changes little (the tint is slightly dependent on a viewing angle).

In this way, the present invention has realized the laminate 20 (the decorative sheet 10 and the molded article) having the depth of color and metallic gloss.

The action described above is exhibited not only in a case where the cholesteric liquid crystal layer is used as the reflection layer 16, but also in a case where the reflection layer is formed of a material having wavelength selectivity in reflection such as a case where the reflection layer 16 is formed of a dielectric multilayer film.

In a case where the laminate according to the embodiment of the present invention does not include the colored transmission layer 18, visible lights in all wavelength ranges are incident on the reflection layer 16. Accordingly, in a case where the laminate is obliquely observed, due to the change in a selective reflection wavelength of the reflection layer 16, for example, green light is observed, that is, the observed tint greatly changes. In other words, in a case where the laminate has no colored transmission layer 18, the dependency of tint on a viewing angle increases. Furthermore, although the reflection wavelength changes, the obliquely incident light is also reflected from the reflection layer 16. Therefore, the amount of light reflected from the reflection layer 16 is the same as the amount of light reflected in a case where the laminate is observed from the front. As a result, light and shade change little. That is, in a case where the laminate has no colored transmission layer 18, the dependency of light and shade on a viewing angle is reduced.

In a case where the laminate has no reflection layer 16, even though the laminate is observed in any direction, only red, which is the color of the colored transmission layer 18, is visible to the observer. Therefore, in a case where the observation direction is changed, light and shade change little, and metallic gloss becomes insufficient. That is, in a case where the laminate has no reflection layer 16, the dependency of light and shade on a viewing angle is reduced, and metallic gloss becomes insufficient.

In a case where the laminate has no absorption layer 14 and in a case where the absorption layer 14 does not absorb the lights transmitted through the colored transmission layer 18, all the lights transmitted through the colored transmission layer 18 are reflected and observed by the observer O. Consequently, metallic gloss becomes insufficient.

In a case where the reflection layer 16 does not reflect the lights transmitted through the colored transmission layer 18, even though the laminate is observed in any direction, the laminate with low brightness is observed all the time. That is, in a case where the reflection layer 16 does not reflect the light transmitted through the colored transmission layer 18, the dependency of light and shade on a viewing angle is reduced.

As described above, the laminate according to the embodiment of the present invention may have a plurality of reflection layers 16.

For example, in a case where the reflection layer 16 is formed of a cholesteric liquid crystal layer, the reflection layer 16 only reflects either right circular polarization or left circular polarization. According to these properties, two reflection layers 16 having the same (approximately the same) central wavelength of selective reflection may be formed such that one reflection layer 16 reflects right circular polarization and the other reflection layer 16 reflects left circular polarization. That is, the sense of a helix of the cholesteric liquid crystal layer may vary between the reflection layers. In this way, the amount of reflected light of a predetermined color can be doubled, and a laminate having better metallic gloss can be obtained.

As described above, in the laminate according to the embodiment of the present invention, a phase difference layer and the like may be combined with the reflection layer 16. For example, two identical reflection layers formed of the same cholesteric liquid crystal layer may be formed, and a λ/2 plate may be interposed therebetween. In this way, the upper reflection layer and the lower reflection layer reflect circular polarization in the opposite direction. Therefore, similarly to the above, the amount of reflected light of a predetermined color can be doubled, and a laminate having better metallic gloss can be obtained.

In the laminate according to the embodiment of the present invention, the reflection layer may have a region, which has a central wavelength of selective reflection in a visible range and reflects light transmitted through the colored transmission layer, in at least a portion thereof. Accordingly, the reflection layer may have a region, which does not reflect the light transmitted through the colored transmission layer, in a portion thereof.

Furthermore, the reflection layer may have a plurality of regions among which the central wavelength of selective reflection varies. That is, in the reflection layer, a plurality of regions among which the central wavelength of selective reflection varies may be formed by patterning. In this way, it is possible to prepare a laminate (a decorative sheet and a molded article) which has metallic gloss and depth of color according to the observation direction and in which color and/or patterns and the like change.

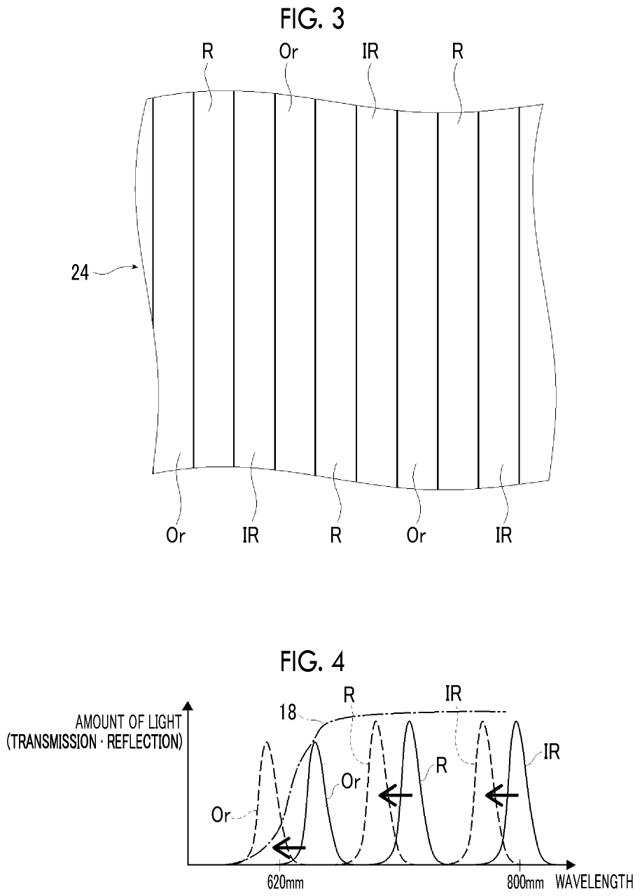

FIG. 3 shows an example of the reflection layer described above.

A reflection layer 24 has three regions consisting of a region IR, a region R, and a region Or among which a central wavelength of selective reflection varies. As shown in FIG. 3, in the reflection layer 24, each of the region IR, the region R, and the region Or is in the form of a belt. The region IR, the region R, and the region Or are repeatedly formed in this order in a direction orthogonal to the longitudinal direction of the belt.

In the laminate using the reflection layer 24, the colored transmission layer 18 and the absorption layer 14 are the same as those in the aforementioned laminate. For example, similarly to the laminate 20 shown in FIG. 1, the laminate using the reflection layer 24 is constituted with the colored transmission layer 18, the reflection layer 24, and the absorption layer 14 in this order form the observation side.

In the constitution using the reflection layer 24, the laminate according to the embodiment of the present invention just needs to have the colored transmission layer 18, the reflection layer 24, and the absorption layer 14 in this order. Accordingly, similarly to the constitution shown in FIG. 2, the laminate may have a constitution in which the reflection layer 24 is on one surface of the base material 12 and the absorption layer 14 is on the other surface of the base material 12.

FIG. 4 conceptually shows the characteristics of a selective reflection wavelength of each of the regions constituting the reflection layer 24 and the characteristics of transmission light amount of the colored transmission layer 18 with respect to a wavelength. In FIG. 4, the abscissa shows a wavelength [nm], and the ordinate shows an amount of light. Note that the ordinate shows a transmission light amount for the colored transmission layer 18 and a reflection light amount for each of the regions in the reflection layer 24.

The reflection layer 24 is, for example, a cholesteric liquid crystal layer reflecting right circular polarization.

As shown in FIG. 4, the region IR in the reflection layer 24 is a region having a central wavelength of selective reflection in infrared light close to the range of red light. The region R in the reflection layer 24 is a region having a central wavelength of selective reflection around the central part of the range of red light. The region Or of the reflection layer is a region having a central wavelength of selective reflection in a short wavelength range in the range of red light.

As shown in FIG. 4 by a dotted line, the colored transmission layer 18 transmits red light and light having a wavelength longer than that of red light and absorbs other visible lights.

As shown in FIG. 1 by the arrow a, in a case where the observer O observes the laminate having the reflection layer 24 from the front, just as the laminate 20 described above, among visible lights, only red light is transmitted, and the transmitted red light is incident on the reflection layer 24.

As described above, the region IR in the reflection layer 24 is a region having a central wavelength of selective reflection in infrared light close to the range of red light. Accordingly, in a case where the laminate is observed from the front, because the region IR reflects only infrared light and does not reflect visible light, the region IR looks black (dark red) just like shade.

The region R in the reflection layer 24 is a region having a central wavelength of selective reflection around the central part of the range of red light. Accordingly, in a case where the laminate is observed from the front, because the region R reflects the light having a wavelength at the center of the range of red light, the region R looks red with metallic gloss.

The region Or in the reflection layer 24 is a region having a central wavelength of selective reflection in a short wavelength range in the range of red light. Accordingly, in a case where the laminate is observed from the front, because the region Or reflects light having a short wavelength in the range of red light, the region Or looks orange with metallic gloss.

The light transmitted through the reflection layer 24 is incident on and absorbed into the absorption layer 14 as described above.

That is, in a case where the observer O observes the laminate having the reflection layer 24 from the front, in the laminate, the region IR looks like a black stripe, the region R looks like a red stripe, and the region Or looks like a stripe of red close to orange.

In contrast, as shown in FIG. 1 by the arrow b, in a case where the laminate having the reflection layer 24 is obliquely observed, similarly to the above, among visible lights, only red light is transmitted, and the transmitted red light is incident on the reflection layer 24.

In a case where the reflection layer 24 is obliquely observed, that is, in a case where light is obliquely incident on the reflection layer 24, as described above, a central wavelength of selective reflection by the reflection layer 24 shifts to a short wavelength side.

The region IR in the reflection layer 24 is a region having a central wavelength of selective reflection in infrared light close to the range of red light. Accordingly, in a case where the laminate is obliquely observed, the central wavelength of selective reflection of the region IR shifts to a short wavelength side as shown in FIG. 4 by a broken line and becomes the wavelength of red light. As a result, the region IR, which looks black (dark red) in a case where the laminate is observed from the front, looks red with metallic gloss in a case where the laminate is obliquely observed.

The region R in the reflection layer 24 is a region having a central wavelength of selective reflection around the central part in the range of red light. Accordingly, in a case where the laminate is obliquely observed, the central wavelength of selective reflection of the region R shifts to a short wavelength side as shown in FIG. 4 by a broken line and becomes a wavelength close to the short wavelength of red light. As a result, the region R, which looks red in a case where the laminate is observed from the front, looks orange with metallic gloss in a case where the laminate is obliquely observed.

The region Or in the reflection layer is a region having a central wavelength of selective reflection in a short wavelength range in the range of red light. Accordingly, in a case where the laminate is obliquely observed, the central wavelength of selective reflection of the region Or shifts to a short wavelength side as shown in FIG. 4 by a broken line and becomes a wavelength which is shorter than that of red light and is not transmitted through the colored transmission layer 18 as shown in FIG. 4 by a dotted line. That is, in a case where the laminate is obliquely observed, the light reflected from the region Or is not transmitted through the colored transmission layer 18. As a result, the region Or, which looks orange in a case where the laminate is observed from the front, darkens and looks black (dark red) in a case where the laminate is obliquely observed.

That is, in a case where the observer O observes the laminate having the reflection layer 24 from the front, in the laminate, the region IR looks like a black (dark red) stripe pattern, the region R looks like a red stripe pattern, and the region Or looks like an orange stripe pattern. However, in a case where the laminate is obliquely observed, in the laminate, the region IR looks like a red stripe pattern, the region R looks like an orange stripe pattern, and the region Or looks like a black (dark red) stripe pattern.

In other words, the laminate comprising the reflection layer 24 having a plurality of regions among which the central wavelength of selective reflection varies is a laminate whose color and pattern change according to the observation direction. Furthermore, similarly to the laminate 20 shown in FIG. 1, in the laminate comprising the reflection layer 24, all the regions have metallic gloss. In addition, as described above, the laminate comprising the reflection layer 24 shows a great change in light and shade and a small change in tint and has depth of color.

The reflection layer 24 having a plurality of regions among which the central wavelength of selective reflection varies can be formed by various known methods.

Examples thereof include a method of coating the absorption layer 14 (base material 12) with a polymerizable liquid crystal composition in forming the reflection layer 16 of the laminate 20, irradiating the applied polymerizable liquid crystal composition with light by covering the composition with a mask according to the regions among which the central wavelength of selective reflection varies, then irradiating the composition after removing the mask such that Helical Twisting Power (HTP) of the chiral agent contained in the polymerizable liquid crystal composition varies among the regions, and then aligning the polymerizable liquid crystal compound in a cholesteric liquid crystalline phase.

In this case, the larger the exposure amount is in a region, the longer the central wavelength of selective reflection of the cholesteric liquid crystal layer can be.

The reflection layer having a plurality of regions among which the central wavelength of selective reflection varies is not limited to the constitution having regions in the form of stripes described above, and can use various constitutions.

For example, in a region taking up half of the reflection layer, an A-shaped region formed of a cholesteric liquid crystal layer having the same central wavelength of selective reflection as the region IR is formed. Furthermore, in a region taking up the other half of the reflection layer, a B-shaped region formed of a cholesteric liquid crystal layer having the same central wavelength of selective reflection as the region Or is formed.

In this way, a laminate is obtained from which B in orange with metallic gloss and A in dark red are observed (or, A is not observed) in a case where the laminate is observed from the front, and B in dark red and A in red with metallic gloss are observed in a case where the laminate is obliquely observed.

Hitherto, the laminate, the decorative sheet, and the molded article according to the embodiment of the present invention have been specifically described. However, the present invention is not limited to the examples described above. It goes without saying that as long as the gist of the present invention is maintained, the present invention may be ameliorated or modified in various ways.

### EXAMPLES

Hereinafter, based on specific examples of the present invention, the present invention will be described in more detail.

The materials, amounts of the materials used, treatment contents, treatment procedure, and the like shown in the following examples can be appropriately modified as long as the gist of the present invention is maintained. Accordingly, the scope of the present invention is not limited to the following specific examples.

### Preparation of Polymerizable Liquid Crystal Composition

By mixing together the following components according to the composition described in Table 1, polymerizable liquid crystal compositions 1 to 6 were obtained.

Each of the polymerizable liquid crystal compositions was prepared using a solvent (toluene, boiling point: 111° C., solubility parameter: 8.9 (cal/cm³)^{1/2}) such that a concentration of solid contents in the composition became 24% by mass.

Each of the numerical values in Table 1 represents a content (part by mass) of each component with respect to the total solid content in the polymerizable liquid crystal composition.

TABLE 1

| | Polymerizable liquid crystal composition (part by mass) | | | | | |
|---|---|---|---|---|---|---|
| | 1 | 2 | 3 | 4 | 5 | 6 |
| Liquid crystal | 90 | 90 | 13 | 13 | 90 | 90 |
| compound A | | | | | | |
| Liquid crystal | 10 | 10 | | | 10 | 10 |
| compound B | | | | | | |
| liquid crystal | | | 55 | 55 | | |
| compound C | | | | | | |
| Liquid crystal | | | 30 | 30 | | |
| compound D | | | | | | |
| Liquid crystal | | | 2 | 2 | | |
| compound E | | | | | | |
| Chiral agent a | 44 | | 4.0 | | 5.5 | 6.5 |
| Chiral agent b | | 7.8 | | 9.2 | | |
| Surfactant a | 0.05 | 0.05 | 0.05 | 0.05 | 0.05 | 0.05 |
| Surfactant b | 0.02 | 0.02 | 0.02 | 0.02 | 0.02 | 0.02 |
| Polymerization | 3 | 3 | 3 | 3 | 3 | 3 |
| initiator | | | | | | |
| Sensitizer | 1 | 1 | 1 | 1 | 1 | 1 |

The components in Table 1 are as below.

### Liquid Crystal Compound

Liquid crystal compound A (compound represented by the following formula)

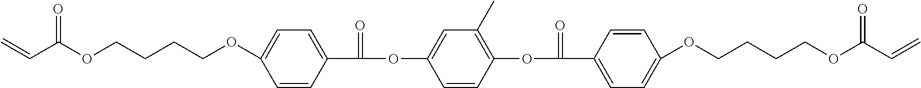 [SMILES: C=CC(=O)OCCCCOc1ccc(C(=O)Oc2ccc(OC(=O)c3ccc(OCCCCOC(=O)C=C)cc3)c(C)c2)cc1]

The liquid crystal compound A was synthesized with reference to paragraph “0164” in JP2014-198814A.
Liquid crystal compound B PALIOCOLOR LC242 (manufactured by BASF SE)
Liquid crystal compound C (compound represented by the following formula)

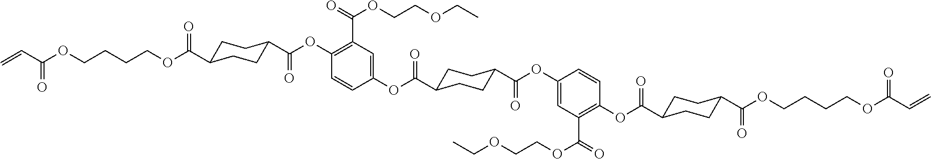 [SMILES: C=CC(=O)OCCCCOC(=O)C1CCC(C(=O)Oc2ccc(OC(=O)C3CCC(C(=O)Oc4ccc(OC(=O)C5CCC(C(=O)OCCCCOC(=O)C=C)CC5)c(C(=O)OCCOCC)c4)CC3)cc2C(=O)OCCOCC)CC1]

Liquid crystal compound D (compound represented by the following formula)

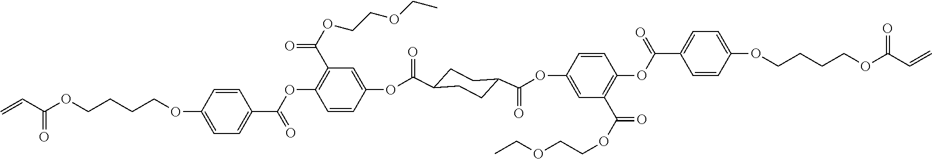 [SMILES: C=CC(=O)OCCCCOc1ccc(C(=O)Oc2ccc(OC(=O)C3CCC(C(=O)Oc4ccc(OC(=O)c5ccc(OCCCCOC(=O)C=C)cc5)c(C(=O)OCCOCC)c4)CC3)cc2C(=O)OCCOCC)cc1]

Liquid crystal compound E (compound represented by the following formula)

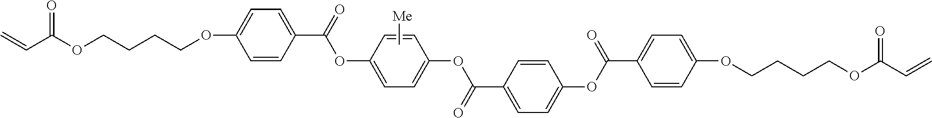

Chiral agent a (compound represented by the following formula)

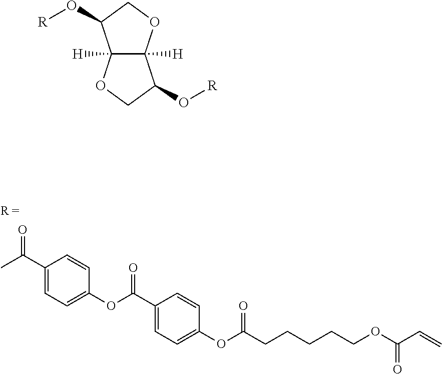

Chiral agent b (compound represented by the following formula)

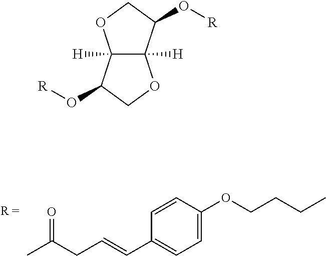

Surfactant a (compound represented by the following formula)

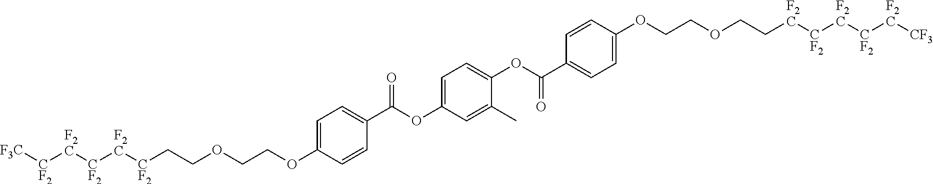 [SMILES: Cc1cc(OC(=O)c2ccc(OCCOCCC(F)(F)C(F)(F)C(F)(F)C(F)(F)C(F)(F)C(F)(F)F)cc2)ccc1OC(=O)c1ccc(OCCOCCC(F)(F)C(F)(F)C(F)(F)C(F)(F)C(F)(F)C(F)(F)F)cc1]

Surfactant b (compound represented by the following formula)

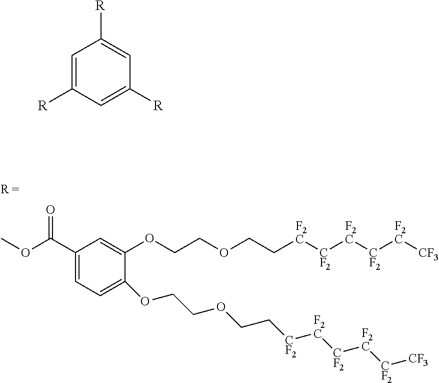

Polymerization initiator (IRGACURE 907)

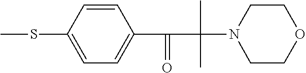 [SMILES: CSc1ccc(C(=O)C(C)(C)N2CCOCC2)cc1]

Sensitizer (KAYACURE DETX-S)

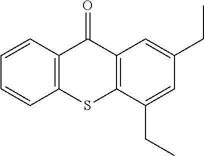 [SMILES: CCc1cc(CC)c2sc3ccccc3c(=O)c2c1]

### Formation of Cholesteric Liquid Crystal Layer

By coating a PET film with each of the polymerizable liquid crystal compositions, a layer formed of the polymerizable liquid crystal composition was formed on the PET film.

The PET film was left to stand for 2 minutes at room temperature. After being left to stand, the PET film was put into an oven and heated for 2 minutes at 90° C. such that the liquid crystal compound was aligned in a cholesteric liquid crystalline phase.

After being heated, the PET film was taken out of the oven, the polymerizable liquid crystal composition was irradiated with light at 500 mJ/cm² in the air such that the layer of the polymerizable liquid crystal composition was cured, thereby obtaining a cholesteric liquid crystal layer.

For the obtained cholesteric liquid crystal layer, by using a spectrophotometer UV3150 (manufactured by Shimadzu Corporation), the direction of selectively reflected circular polarization and a central wavelength of selective reflection [nm] were determined. The results are shown in Table 2.

TABLE 2

| | Cholesteric liquid crystal layer | | | | | |
|---|---|---|---|---|---|---|
| | A | B | C | D | E | F |
| Polymerizable liquid crystal | 1 | 2 | 3 | 4 | 5 | 6 |
| composition | | | | | | |
| Direction of circular | Right | Left | Right | Left | Right | Right |
| polarization selectively | | | | | | |
| reflected | | | | | | |
| Central wavelength of | 650 | 650 | 650 | 650 | 520 | 445 |
| selective reflection [nm] | | | | | | |

### Example 1

As a base material, a colorless transparent PET film (manufactured by Toyobo Co., Ltd., COSMOSHINE A4100) was prepared. One surface of the PET film is a surface having undergone an easy adhesion treatment, and the other surface thereof is a normal smooth surface.

By using a wire bar, the easily adhesive surface of the base material was coated with a polymerizable liquid crystal composition 1 such that the film thickness became 4 μm. The base material coated with the polymerizable liquid crystal composition was put into an oven and heated for 30 seconds at 100° C. such that the polymerizable liquid crystals were aligned in a cholesteric liquid crystalline phase.

The base material was taken out of the oven and irradiated with light at 500 mJ/cm² at 30° C. in nitrogen such that the polymerizable liquid crystal composition 1 was cured, thereby preparing a reflection layer (cholesteric liquid crystal layer). The thickness of the reflection layer was 4 μm.

As a result of visual observation, the formed reflection layer was found to have a shade of red. Furthermore, the transmittance of the reflection layer (cholesteric liquid crystal layer formed of the polymerizable liquid crystal composition 1) at the central wavelength of selective reflection (650 nm) was measured using a spectrophotometer (manufactured by Shimadzu Corporation, a spectrophotometer UV3150). As a result, the transmittance was found to be 50%.

A mixture was prepared as below.

| | | |
|---|---|---|
| Propylene glycol monomethyl ether acetate | 58 | parts by mass |
| solution (solid contents: 50%) containing | | |
| benzyl methacrylate/methacrylic acid/ | | |
| hydroxyethyl methacrylate copolymer | | |
| resin (molar ratio: 69/13/18, acid value: | | |
| 47, hydroxyl number: 65, mass-average | | |
| molecular weight: 20,000) | | |
| C.I. Pigment Red 254 (manufactured by | 20 | parts by mass |
| TOKYO CHEMICAL INDUSTRY CO., LTD.) | | |
| Propylene glycol monomethyl ether acetate | 150 | parts by mass |
| (solvent) | | |

The above components were dispersed with a sand mill for 24 hours.

Then, radiation-sensitive components, a thermal polymerization inhibitor, and a solvent described below were added to and mixed with the prepared dispersion, thereby obtaining a mixture.

| | | |
|---|---|---|
| The following acrylate monomer | 23 | parts by mass |
| 2,6-Di(trichloromethyl)-S-triazine | 3 | parts by mass |
| (photopolymerization initiator) | | |
| Hydroquinone monomethyl ether | 0.01 | parts by mass |
| (polymerization inhibitor) | | |
| 3-Ethoxyethyl propylene glycol | 70 | parts by mass |
| acetate (solvent) | | |

(Acrylate monomer: hexaacrylate.4-[o-bromo-p-N,N-di(ethoxycarbonyl)aminophenyl] obtained by adding 6 ethylene oxides to dipentaerythritol)

A surfactant (manufactured by TAKEMOTO OIL & FAT Co., Ltd., D6112W) was added to the mixture prepared as above in an amount of 0.3% by mass with respect to the total mass of the composition, and the mixture was filtered through a filter having a pore size of 5 μm, thereby obtaining a color paint for forming a colored transmission layer.

The top of the formed reflection layer was coated with the color paint and then dried, thereby forming a colored transmission layer having a thickness of 3 μm.

On the same PET film as the base material, a colored transmission layer was formed exactly in the same manner as that adopted for providing the colored transmission layer formed on top of the reflection layer.

For the colored transmission layer, a transmittance at a wavelength that reduced most the transmittance and a transmittance at the central wavelength of selective reflection of the reflection layer were measured using a spectrophotometer (manufactured by Shimadzu Corporation, spectrophotometer UV3150). As a result, the transmittance (transmittance A) at a wavelength that reduced most the transmittance was 6%, and the transmittance (transmittance B) at the central wavelength of selective reflection of the reflection layer was 83%.

Furthermore, as an absorption layer, a black PET film (manufactured by TORAY INDUSTRIES, INC., LUMIRROR) having a thickness of 100 μm was bonded to a surface of the base material that was opposite to the surface on which the reflection layer was formed.

The total light transmittance of the black PET film was 0%. The black PET film was bonded to the base material by using an optical pressure sensitive adhesive.

In this way, a decorative sheet having a laminate comprising a colored transmission layer, a reflection layer, and an absorption layer in this order was prepared.

In a case where the decorative sheet (laminate) was exposed to light and visually observed from the front, red metallic gloss was observed. Furthermore, in a case where half of the decorative sheet was bent such that it inclined about 45°, metallic gloss was reduced, the decorative sheet darkened, and a big change in brightness was observed.

### Example 2

A decorative sheet having a laminate comprising a colored transmission layer, a reflection layer, and an absorption layer in this order was prepared in the same manner as in Example 1, except that after a reflection layer was formed on a surface of the base material by using the polymerizable liquid crystal composition 1, a second reflection layer was formed as well by using a polymerizable liquid crystal composition 2. That is, the laminate has a reflection layer having a central wavelength of selective reflection of 650 nm and reflecting right circular polarization and a reflection layer having a central wavelength of selective reflection of 650 nm and reflecting left circular polarization.

In a case where the decorative sheet (laminate) is exposed to light from the front and visually observed, because both the right and left circular polarizations having a central wavelength of selective reflection of 650 nm were reflected, red metallic gloss stronger than that in Example 1 was observed. Furthermore, in a case where half of the decorative sheet was bent such that it inclined about 45°, metallic gloss was greatly reduced, and the decorative sheet darkened. Therefore, a change in brightness that was bigger than that in Example 1 was observed.

### Example 3

A decorative sheet having a laminate comprising a colored transmission layer, a reflection layer, and an absorption layer in this order was prepared in the same manner as in Example 1, except that the normal smooth surface of the base material was subjected to a rubbing treatment by using a rubbing machine, and a reflection layer was formed on the surface having undergone the rubbing treatment.

### Example 4

A decorative sheet having a laminate comprising a colored transmission layer, a reflection layer, and an absorption layer in this order was prepared in the same manner as in Example 2, except that the normal smooth surface of the base material was subjected to a rubbing treatment by using a rubbing machine, and a reflection layer was formed on the surface having undergone the rubbing treatment.

### Example 5

A decorative sheet having a laminate comprising a colored transmission layer, a reflection layer, and an absorption layer in this order was prepared in the same manner as in Example 1, except that a polymerizable liquid crystal composition 3 was used as a polymerizable liquid crystal composition for forming a reflection layer.

### Example 6

A decorative sheet having a laminate comprising a colored transmission layer, a reflection layer, and an absorption layer in this order was prepared in the same manner as in Example 2, except that the polymerizable liquid crystal composition 3 and a polymerizable liquid crystal composition 4 were used as polymerizable liquid crystal compositions for forming a reflection layer.

### Example 7

A decorative sheet having a laminate comprising a colored transmission layer, a reflection layer, and an absorption layer in this order was prepared in the same manner as in Example 5, except that the normal smooth surface of the base material was subjected to a rubbing treatment by using a rubbing machine, and a reflection layer was formed on the surface having undergone the rubbing treatment.

### Example 8

A decorative sheet having a laminate comprising a colored transmission layer, a reflection layer, and an absorption layer in this order was prepared in the same manner as in Example 6, except that the normal smooth surface of the base material was subjected to a rubbing treatment by using a rubbing machine, and a reflection layer was formed on the surface having undergone the rubbing treatment.

### Example 9

A decorative sheet having a laminate comprising a colored transmission layer, a reflection layer, and an absorption layer in this order was prepared in the same manner as in Example 1, except that a polymerizable liquid crystal composition 5 was used as a polymerizable liquid crystal composition for forming a reflection layer, and a coloring agent added to a paint for forming a colored transmission layer was changed to a green coloring agent (manufactured by TOKYO CHEMICAL INDUSTRY CO., LTD., Pigment Green 7).

### Example 10

A decorative sheet having a laminate comprising a colored transmission layer, a reflection layer, and an absorption layer in this order was prepared in the same manner as in Example 1, except that a polymerizable liquid crystal composition 6 was used as a polymerizable liquid crystal composition for forming a reflection layer, and a coloring agent added to a paint for forming a colored transmission layer was changed to a blue coloring agent (manufactured by TOKYO CHEMICAL INDUSTRY CO., LTD., Pigment Alpha Blue 15).

### Example 11

A decorative sheet having a laminate comprising a colored transmission layer, a reflection layer, and an absorption layer in this order was prepared in the same manner as in Example 1, except that the method for coating the base material with the polymerizable liquid crystal composition at the time of forming a reflection layer was changed to spray coating from wire bar coating.

### Comparative Example 1

A decorative sheet was prepared in the same manner as in Example 1, except that an absorption layer was not formed.

### Comparative Example 2

A decorative sheet was prepared in the same manner as in Example 1, except that a reflection layer was not formed.

### Comparative Example 3

A decorative sheet was prepared in the same manner as in Example 1, except that a colored transmission layer was not formed.

### Comparative Example 4

A decorative sheet having a laminate comprising a colored transmission layer, a reflection layer, and an absorption layer in this order was prepared in the same manner as in Example 1, except that a coloring agent added to a paint for forming a colored transmission layer was changed to a green coloring agent (manufactured by TOKYO CHEMICAL INDUSTRY CO., LTD., Pigment Green 7).

### Comparative Example 5

A decorative sheet having a laminate comprising a colored transmission layer, a reflection layer, and an absorption layer in this order was prepared in the same manner as in Example 1, except that a coloring agent added to a paint for forming a colored transmission layer was changed to a blue coloring agent (manufactured by TOKYO CHEMICAL INDUSTRY CO., LTD., Pigment Alpha Blue 15).

### Evaluation

For the prepared decorative sheets, a change in brightness occurring in a case where the observation angle is changed, a change in tint occurring in a case where the observation angle is changed, and metallic gloss were evaluated.

### Change in Brightness Occurring in a Case Where Observation Angle is Changed

By using an automated absolute reflectance measurement system (manufactured by JASCO., ARMN-735), an area of a reflection peak detected at 20° by allowing measurement light to incident on the decorative sheet at 10° and an area of a reflection peak detected at 50° by allowing measurement light to incident on the decorative sheet at 40° were calculated. The area was defined as “reflection amount”. In all cases, “angle” means an angle with respect to a normal line of the decorative sheet (direction orthogonal to the surface of the sheet).

At this time, a value of [(reflection amount at an incident angle of 10°)/(reflection amount at an incident angle of 50°)] was calculated and adopted as a degree of change in brightness occurring in a case where the observation angle is changed.

In view of depth of color, it is preferable that brightness greatly changes in a case where the observation angle is changed, that is, in a case where the incident angle of the measurement light is changed. The evaluation standards are as below.

A: A change in brightness is equal to or greater than 10.

B: A change in brightness is equal to or greater than 5 and less than 10.

C: A change in brightness is equal to or greater than 2 and less than 5.

D: A change in brightness is less than 2.

### Change in Tint Occurring in a Case Where Observation Angle is Changed

Under the same condition as that adopted for measuring the change in brightness occurring in a case where the observation angle is changed, a central wavelength of reflection [nm] was measured at each angle. The central wavelength of reflection is a wavelength at which the amount of light was maximized among lights having various wavelengths received by a detector.

At this time, a value of [(central wavelength of reflection at an incident angle of 10°)−(central wavelength of reflection at an incident angle of 50°)] was calculated and adopted as a degree of change in tint.

In view of depth of color, it is preferable that tint does not change too much even though the observation angle is changed, that is, even though the incident angle of the measurement light is changed. The evaluation standards are as below.

A: A change in tint is less than 30 nm.

B: A change in tint is equal to or greater than 30 nm and less than 50 nm.

C: A change in tint is equal to or greater than 50 nm and less than 80 nm.

D: A change in tint is equal to or greater than 80 nm.

### Metallic Gloss

Each of the decorative sheets was placed on a horizontal stand and irradiated with white light emitting diode (LED) in a normal direction of the decorative sheet. In this state, 10 observers were asked to observe the decorative sheet at various angles and to determine whether they sensed metallic gloss. The evaluation standards are as below.

A: Nine to ten observers determined that the decorative sheet had metallic gloss.

B: Five to eight observers determined that the decorative sheet had metallic gloss.

C: Two to four observers determined that the decorative sheet had metallic gloss.

D: No observer or one observer determined that the decorative sheet had metallic gloss.

The results are shown in Table 3.

For all the decorative sheets, in the same manner as in Example 1, the color of the decorative sheet seen in a case where the decorative sheet was visually observed from the front, the shade of color of the decorative sheet seen in a case where the reflection layer was visually observed, the transmittance at the central wavelength of selective reflection of the reflection layer, the transmittance (transmittance A) at a wavelength that reduced most the transmittance of the colored transmission layer, and the transmittance (transmittance B) of the colored transmission layer at the central wavelength of selective reflection of the reflection layer were measured.

The results are also described in Table 3.

TABLE 3

| | | Example | | | | | | | |
|---|---|---|---|---|---|---|---|---|---|
| | | 1 | 2 | 3 | 4 | 5 | 6 | 7 | 8 |
| Absorption | Presence or | Present | Present | Present | Present | Present | Present | Present | Present |
| layer | absence | | | | | | | | |
| Reflection | Formation surface | Easy | Easy | Untreated | Untreated | Easy | Easy | Untreated | Untreated |
| layer | | adhesion | adhesion | | | adhesion | adhesion | | |
| | Rubbing | N/A | N/A | Performed | Performed | N/A | N/A | Performed | Performed |
| | Liquid crystal | 1 | 1/2 | 1 | 1/2 | 3 | 3/4 | 3 | 3/4 |
| | composition | | | | | | | | |
| | Central wavelength | 650 | 650 | 650 | 650 | 650 | 650 | 650 | 650 |
| | [μm] | | | | | | | | |
| | Shade | Red | Red | Red | Red | Red | Red | Red | Red |
| | Formation method | Coating | Coating | Coating | Coating | Coating | Coating | Coating | Coating |
| | Transmittance [%] | 50 | 30 | 45 | 2 | 54 | 40 | 52 | 40 |
| Colored | Coloring agent | Red | Red | Red | Red | Red | Red | Red | Red |
| layer | Transmittance A | 6 | 6 | 6 | 6 | 6 | 6 | 6 | 6 |
| | [%] | | | | | | | | |
| | Transmittance B | 83 | 83 | 83 | 83 | 83 | 83 | 83 | 83 |
| | [%] | | | | | | | | |
| Color seen in a case where | | Red | Red | Red | Red | Red | Red | Red | Red |
| decorative sheet is visually | | | | | | | | | |
| observed from front | | | | | | | | | |
| Change in brightness | | B | B | B | B | A | A | A | A |
| Change in tint | | B | B | B | B | A | A | A | A |
| Metallic gloss | | A | A | A | A | A | A | A | A |
| | | Comparative Example | | | | | | | |
| | | 9 | 10 | 11 | 1 | 2 | 3 | 4 | 5 |
| Absorption | Presence or | Present | Present | Present | Absent | Present | Present | Present | Present |
| layer | absence | | | | | | | | |
| Reflection | Formation surface | Easy | Easy | Easy | Easy | | Easy | Easy | Easy |
| layer | | adhesion | adhesion | adhesion | adhesion | | adhesion | adhesion | adhesion |
| | Rubbing | N/A | N/A | N/A | N/A | | N/A | N/A | N/A |
| | Liquid crystal | 5 | 6 | 1 | 1 | | 1 | 1 | 1 |
| | composition | | | | | | | | |
| | Central wavelength | 520 | 445 | 650 | 650 | | 650 | 650 | 650 |
| | [μm] | | | | | | | | |
| | Shade | Green | Blue | Red | Red | | Red | Red | Red |
| | Formation method | Coating | Coating | Spraying | Coating | | Coating | Coating | Coating |
| | Transmittance [%] | 50 | 50 | 50 | 50 | | 50 | 50 | 50 |
| Colored | Coloring agent | Green | Blue | Red | Red | Red | | Green | Blue |
| layer | Transmittance A | 2 | 10 | 6 | 6 | 6 | | 2 | 10 |
| | [%] | | | | | | | | |
| | Transmittance B | 82 | 75 | 83 | 83 | 83 | | 16 | 16 |
| | [%] | | | | | | | | |

| | | | | | | | | |
|---|---|---|---|---|---|---|---|---|
| Color seen in a case where | Green | Blue | Red | Red | Dark red | Red | Black | Black |
| decorative sheet is visually | | | | | | | | |
| observed from front | | | | | | | | |
| Change in brightness | B | A | B | A | D | D | D | D |
| Change in tint | A | A | B | A | A | D | D | D |
| Metallic gloss | A | A | A | D | D | A | C | C |

All the absorption layers are black and have a total light transmittance of 0%.
The central wavelength in a reflection layer means a central wavelength of selective reflection.
The transmittance in a reflection layer means a transmittance at the central wavelength of selective reflection.
The colored layer is a colored transmission layer.
The transmittance A is a transmittance at a wavelength reducing most the transmittance, and the transmittance B is a transmittance at a central wavelength of selective reflection of a reflection layer.

As shown in Table 3, the decorative sheet according to the embodiment of the present invention having the laminate according to the embodiment of the present invention has excellent metallic gloss. Furthermore, in the decorative sheet, light and shade greatly change in a case where the observation angle is changed (light and shade is greatly dependent on an angle), and tint changes little in a case where the observation direction is changed (tint is slightly dependent on a viewing angle). Therefore, the decorative sheet has excellent depth of color.

Among the examples, Examples 3, 4, 7, and 8 in which the base material is rubbed are laminates having a regular reflection layer, and others are laminates having a scattering reflection layer. While the laminate was being observed, the decorative sheet was inclined and obliquely observed. As a result, in the laminate having a regular reflection layer, light and shade greatly changed even though the angle was slightly changed. In the laminate having a scattering reflection layer, although light and shade slightly changed even though the angle was changed, the amount of change in light and shade remains the same as described in Examples.

In contrast, Comparative Example 1 without a reflection layer does not have metallic gloss. In Comparative Example 2 without a reflection layer, light and shade slightly change even though the observation angle is changed. Therefore, Comparative Example 2 is poor in terms of depth of color and does not have metallic gloss. In Comparative Example 3 without a colored transmission layer, in a case where the observation angle is changed, light and shade change little but tint greatly changes. Therefore, Comparative Example 3 does not have depth of color. Comparative Examples 4 and 5 having a reflection layer that does not reflect the light transmitted through the colored transmission layer have weak metallic gloss. In addition, in Comparative Examples 4 and 5, in a case where the observation angle is changed, light and shade change little but tint greatly changes. Therefore, Comparative Examples 4 and 5 do not have depth of color.

### Example 12

### Preparation of Polymerizable Liquid Crystal Composition 7

By dissolving the following components in toluene, a polymerizable liquid crystal composition 7 with a concentration of solid contents of 25% by mass was prepared.

| | | |
|---|---|---|
| Liquid crystal compound A | 90 | parts by mass |
| Liquid crystal compound F | 10 | parts by mass |
| Chiral agent c | 11 | parts by mass |
| Surfactant a | 4 | parts by mass |
| Photo-radical initiator a | 3 | parts by mass |
| Polymerization inhibitor | 1 | parts by mass |

Liquid crystal compound A (compound represented by the following formula)

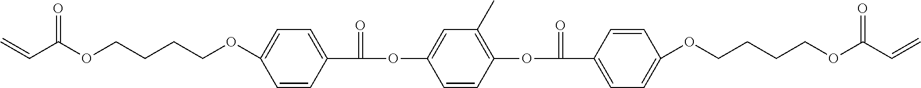 [SMILES: C=CC(=O)OCCCCOc1ccc(C(=O)Oc2ccc(OC(=O)c3ccc(OCCCCOC(=O)C=C)cc3)c(C)c2)cc1]

Liquid crystal compound F (compound represented by the following formula)

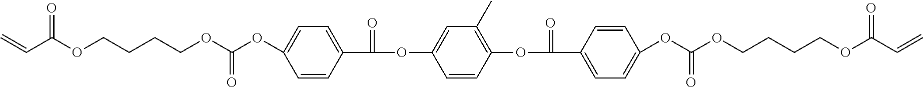 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]

Chiral agent c (compound represented by the following formula)

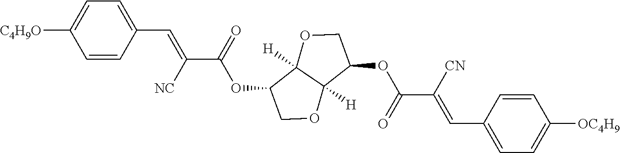

Surfactant a (compound represented by the following formula)

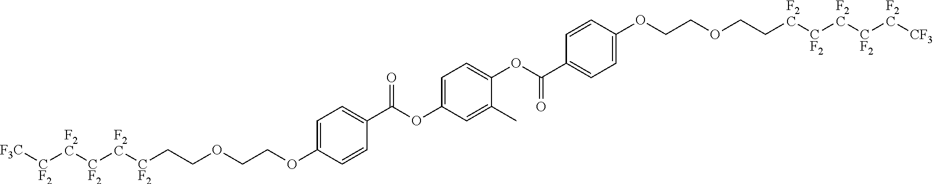 [SMILES: Cc1cc(OC(=O)c2ccc(OCCOCCC(F)(F)C(F)(F)C(F)(F)C(F)(F)C(F)(F)C(F)(F)F)cc2)ccc1OC(=O)c1ccc(OCCOCCC(F)(F)C(F)(F)C(F)(F)C(F)(F)C(F)(F)C(F)(F)F)cc1]

Photo-radical initiator a: IRGACURE 819 manufactured by BASF SE

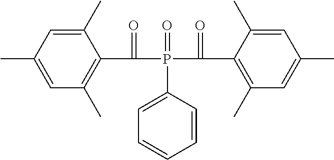

Polymerization inhibitor: IRGANOX 1010 manufactured by BASF SE

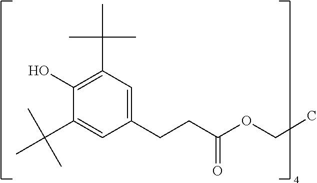

As a base material, a colorless transparent PET film (manufactured by Toyobo Co., Ltd, COSMOSHINE A4100) having a thickness of 100 μm was prepared.

By using a wire bar, one surface of the base material was coated with the polymerizable liquid crystal composition 7.

Then, a light transmitting mask including a light gray region and a dark gray region was put on the base material such that a region of the coating film was covered, and the coating film was exposed at 14 mJ/cm² while being heated at 30° C. in the air. Thereafter, the mask was removed, and the coating film was exposed at 15 mJ/cm² while being heated at 30° C. in the air.

The base material including the exposed coating film was put into an oven and heated at 100° C. such that the liquid crystal compound was aligned in a cholesteric liquid crystalline phase.

The base material was taken out of the oven and irradiated with light at 500 mJ/cm² in nitrogen at 30° C. such that the polymerizable liquid crystal composition 7 was cured, thereby forming a cholesteric liquid crystal layer. The formed cholesteric liquid crystal layer had a thickness of 5 μm.

The surface on the cholesteric liquid crystal layer side (coated surface) was adopted as an observation surface, and the film was analyzed using a spectrophotometer (manufactured by Shimadzu Corporation, spectrophotometer UV3150). As a result, a pattern (red) having a central wavelength of selective reflection of 650 nm was checked in the portion irradiated with light through the light gray region of the mask, and a pattern (green) having a central wavelength of selective reflection of 550 nm was checked in the portion irradiated with light through the dark gray region of the mask. From this result, it was confirmed that two regions between which the central wavelength of selective reflection varies are formed in the cholesteric liquid crystal layer.

Furthermore, as a result of visually observing the observation surface on the cholesteric liquid crystal layer side, a multicolored image having metallic gloss (image colored with red and green) could be checked.

By using the formed cholesteric liquid crystal layer as a reflection layer and a PET film as a base material, a colored transmission layer using a red coloring agent was formed on the surface of the reflection layer in the same manner as in Example 1. Furthermore, on a surface of the base material that was opposite to the reflection layer, an absorption layer using a black PET film was formed in the same manner as in Example 1, thereby preparing a decorative sheet having a laminate comprising a colored transmission layer, a reflection layer, and an absorption layer in this order.

As a result of observing the prepared decorative sheet from the front, a pattern of two colors including a region having red metallic gloss and a black region looking like shade (dark red region) could be checked. In contrast, in a case where the decorative sheet was inclined 45°, the entirety of the decorative sheet darkened (turned dark red), and a pattern could not be checked. Furthermore, in any of the regions, light and shade greatly changed, but tint changed little, which showed that the decorative sheet has depth of color.

### Example 13

In the same manner as in Example 12, a film of the polymerizable liquid crystal composition 7 was formed on a PET film. Then, a light transmitting mask constituted with three regions of a colorless transparent region, a light gray region, and a dark gray region was put on the film such that a region of the coating film was covered. The coating film was exposed at 14 mJ/cm² while being heated at 30° C. in the air. Thereafter, the mask was removed, and the coating film was exposed at 15 mJ/cm² while being heated at 30° C. in the air.

Subsequently, in the same manner as in Example 12, a cholesteric liquid crystal layer was formed.

A surface on the cholesteric liquid crystal layer side (coated surface) was adopted as an observation surface, and the film was analyzed in the same manner as in Example 12. As a result, in a portion irradiated with light through the colorless transparent region of the mask, a pattern (infrared) having a central wavelength of selective reflection of 790 nm was checked. In a portion irradiated with light through the light gray region of the mask, a pattern (red) having a central wavelength of selective reflection of 650 nm was checked. In a portion irradiated with light through the dark gray region of the mask, a pattern (green) having a central wavelength of selective reflection of 550 nm was checked.

From this result, it was confirmed that three regions among which the central wavelength of selective reflection varies are formed in the cholesteric liquid crystal layer.

Furthermore, the observation surface on the cholesteric liquid crystal layer side was visually observed. As a result, a multicolored image having metallic gloss (image colored with black, red, and green) was checked.

Then, by using the cholesteric liquid crystal layer as a reflection layer and a PET film as a base material, a colored transmission layer using a red coloring agent was formed on the surface of the reflection layer in the same manner as in Example 1. Furthermore, on a surface of the base material that was opposite to the reflection layer, an absorption layer using a black PET film was formed in the same manner as in Example 1, thereby preparing a decorative sheet having a laminate comprising a colored transmission layer, a reflection layer, and an absorption layer in this order.

In a case where the prepared decorative sheet was observed from the front, a pattern having two colors could be checked which had two regions black as shade (dark red region) on both sides of a region having red metallic gloss. In contrast, in a case where the decorative sheet was inclined 45°, one of the black regions (dark red regions) became a region having red metallic gloss, and the red region turned black (dark red region). As a result, a pattern could be checked which still had two colors of black and red by including a red region having metallic gloss at the end and two black regions but was different from the pattern checked in a case where the decorative sheet was observed from the front. Furthermore, in any of the regions, light and shade greatly changed, but tint changed little, which showed that the decorative sheet had depth of color.

The results are also described in the following Table 4.

TABLE 4

| | Example 12 | | Example 13 | | |
|---|---|---|---|---|---|
| | Re- | Re- | Re- | Re- | Re- |
| | gion 1 | gion 2 | gion 1 | gion 2 | gion 3 |
| Central wavelength of | 650 | 550 | 790 | 650 | 550 |
| selective reflection [nm] | | | | | |
| Tint seen in a case | Red | Black | Black | Red | Black |
| where decorative sheet | | | | | |
| is observed from front | | | | | |
| Tint seen in a case | Black | Black | Red | Black | Black |
| where decorative sheet | | | | | |
| is observed by being | | | | | |
| inclined 45° | | | | | |

The above results clearly show the effects of the present invention.

The present invention can be suitably used for frames, interiors, and the like of vehicles.

### EXPLANATION OF REFERENCES

10: decorative sheet

12: base material

14: absorption layer

16, 24: reflection layer

18: colored transmission layer

20: laminate

IR, Or, R: region

What is claimed is:

1. A laminate comprising:
a colored transmission layer which transmits light of a predetermined wavelength band and absorbs other lights;
a reflection layer having wavelength selectivity in reflection; and
an absorption layer in this order,
wherein the absorption layer absorbs light transmitted through the colored transmission layer, and
the reflection layer has a region reflecting the light transmitted through the colored transmission layer.

2. The laminate according to claim 1,
wherein the reflection layer does not contain a metal.

3. The laminate according to claim 1,
wherein the reflection layer has at least one of a cholesteric liquid crystal layer or a dielectric multilayer film.

4. The laminate according to claim 1,
wherein the absorption layer is achromatic.

5. The laminate according to claim 1,
wherein the absorption layer is black.

6. The laminate according to claim 1,
wherein a total light transmittance of the absorption layer is equal to or lower than 10%.

7. The laminate according to claim 1,
wherein the reflection layer has a transmittance equal to or lower than 70% at a central wavelength of selective reflection.

8. The laminate according to claim 1,
wherein the reflection layer has a plurality of regions, among which a central wavelength of selective reflection varies, in the same plane.

9. The laminate according to claim 1 comprising:
a plurality of the reflection layers.

10. The laminate according to claim 1,
wherein the reflection layer is a scattering reflection layer.

11. The laminate according to claim 1,
wherein the reflection layer is a regular reflection layer.

12. The laminate according to claim 1,
wherein the colored transmission layer has a transmittance equal to or higher than 50% at the central wavelength of selective reflection of the reflection layer.

13. A decorative sheet comprising:
the laminate according to claim 1.

14. A molded article comprising:
the laminate according to claim 1.
